(19) United States
(12) Patent Application Publication
(10) Pub. No.: US 2025/0386690 A1
(43) Pub. Date: Dec. 18, 2025

(54) DISPLAY MODULE AND DISPLAY DEVICE

(71) Applicant: Hefei Visionox Technology Co., Ltd., Hefei (CN)

(72) Inventor: Wenyu ZENG, Hefei (CN)

(73) Assignee: Hefei Visionox Technology Co., Ltd., Hefei (CN)

(21) Appl. No.: 19/182,625

(22) Filed: Apr. 18, 2025

(30) Foreign Application Priority Data
Jun. 17, 2024 (CN) 202410784135.5

(51) Int. Cl. H10K 59/131; H10K 59/122; H10K 59/80

(52) U.S. Cl. CPC H10K 59/131; H10K 59/122; H10K 59/873; H10K 59/8791

(57) ABSTRACT

The disclosure provides a display module and a display device. The display module includes a display area and a non-display area. The display module further includes a substrate, and a first signal line, an inorganic protective layer, a spacer layer and a polarizer which are disposed on the substrate. The inorganic protective layer is located at least in the non-display area and on a side of the first signal line away from the substrate, the spacer layer is located at least in the non-display area and between the inorganic protective layer and the substrate, and the polarizer is located on a side of the inorganic protective layer facing away from the substrate and covers the display area and extends to the non-display area. In the non-display area, the polarizer includes a first boundary.

### CROSS-REFERENCE TO RELATED APPLICATIONS

The present application claims priority to Chinese Patent Application No. 202410784135.5, entitled “DISPLAY MODULE AND DISPLAY DEVICE” and filed on Jun. 17, 2024, the entire contents of which are incorporated herein by reference.

### FIELD

The disclosure relates to the field of displays, and in particular to a display module and a display device.

### BACKGROUND ART

An organic light-emitting diode (OLED) is an organic thin-film electroluminescent device, which has received great attention and has been widely used in electronic display products thanks to its advantages such as simple preparation process, low cost, low power consumption, high luminance, wide angle of view, high contrast, and enabling flexible display.

### SUMMARY OF THE DISCLOSURE

One embodiment of the disclosure provides a display module. The display module includes a display area and a non-display area. The display module further includes a substrate, and a first signal line, an inorganic protective layer, a spacer layer, and a polarizer which are disposed on the substrate. The inorganic protective layer is located at least in the non-display area and on a side of the first signal line away from the substrate, the spacer layer is located at least in the non-display area and between the inorganic protective layer and the substrate, and the polarizer is located on a side of the inorganic protective layer facing away from the substrate and covers the display area and extends to the non-display area. In the non-display area, the polarizer includes a first boundary, and an overlap region between an orthographic projection of the first signal line on the substrate and an orthographic projection of the spacer layer on the substrate overlaps with an orthographic projection of the first boundary on the substrate.

In the above embodiments, ions overflowing from an edge of the polarizer will be accumulated on the inorganic protective layer and damage the structure of the inorganic protective layer when moving toward the first signal line; and the inorganic protective layer and the first signal line are separated by the spacer layer in the vicinity of the edge of the polarizer, thereby preventing the first signal line from being damaged by corrosion to ensure functions of the display module.

In one embodiment of the disclosure, in the non-display area, the inorganic protective layer includes a second boundary, and the overlap region between the orthographic projection of the first signal line on the substrate and the orthographic projection of the spacer layer on the substrate overlaps with an orthographic projection of the second boundary on the substrate.

In one embodiment, the orthographic projection of the first boundary on the substrate overlaps and is collinear with the orthographic projection of the second boundary on the substrate.

In one embodiment, the orthographic projection of the first boundary on the substrate is located on a side of the orthographic projection of the second boundary on the substrate close to the display area.

In one embodiment, a distance between the orthographic projection of the first boundary on the substrate and the orthographic projection of the second boundary on the substrate is greater than or equal to 130 μm and less than or equal to 220 μm. For example, further, the distance between the orthographic projection of the first boundary on the substrate and the orthographic projection of the second boundary on the substrate is 175 μm. Within this value range, the ion blocking range of the inorganic protective layer can be guaranteed and the width of the non-display area will not be additionally increased, which is conducive to the narrow border design of the display module.

In one embodiment, the non-display area further includes a bend area, and the orthographic projection of the second boundary on the substrate is located between the display area and the bend area.

In one embodiment, an overlap region between the orthographic projection of the first signal line on the substrate, the orthographic projection of the spacer layer on the substrate and an orthographic projection of the inorganic protective layer on the substrate overlaps with the orthographic projection of the first boundary on the substrate.

In one embodiment of the disclosure, in the non-display area, the spacer layer includes a third boundary, and an orthographic projection of the third boundary on the substrate is located on a side of the orthographic projection of the first boundary on the substrate close to the display area.

In one embodiment, in the non-display area, the inorganic protective layer includes a second boundary, and the orthographic projection of the third boundary on the substrate is located on a side of an orthographic projection of the second boundary on the substrate close to the display area.

In one embodiment, in the non-display area, a distance between the orthographic projection of the third boundary on the substrate and the orthographic projection of the first boundary on the substrate is greater than or equal to 80 μm and less than or equal to 170 μm. In this way, the coverage of a portion of the spacer layer that is used for spacing the polarizer apart from the first signal line can be guaranteed, to ensure that the ions accumulated on the inorganic protective layer will not further intrude into the first signal line.

In one embodiment, a distance between the orthographic projection of the third boundary on the substrate and the orthographic projection of the second boundary of the inorganic protective layer on the substrate is greater than or equal to 0.09 mm.

In one embodiment, the distance between the orthographic projection of the third boundary on the substrate and the orthographic projection of the second boundary of the inorganic protective layer on the substrate is greater than or equal to the sum of an attachment tolerance and an alignment tolerance of the polarizer.

In one embodiment, in consideration of the lateral positions of the third boundary of the spacer layer and the second boundary of the inorganic protective layer, i.e., the distance therebetween in a direction parallel to the plane where the substrate is located, the attachment tolerance and the alignment tolerance in the process of bonding the polarizer are considered to ensure that the inorganic protective layer and the spacer layer will be present in the vicinity of the first boundary of the polarizer, ensuring that the edge of the polarizer and the first signal line can still be separated by the spacer layer to ensure the yield of the display module in the actual production process.

In one embodiment, the attachment tolerance is greater than or equal to 0.08 mm, and/or the alignment tolerance is greater than or equal to 0.01 mm.

In one embodiment of the disclosure, the display module further includes at least one dam located in the non-display area. An orthographic projection of the dam on the substrate is located between the display area and the orthographic projection of the first boundary on the substrate.

In one embodiment, the spacer layer is located on a side of the dam away from the display area, and a first gap is provided between the spacer layer and the dam adjacent to the spacer layer. The inorganic protective layer located in the first gap is in contact with the first signal line. There is no spacer layer at the first gap, or the spacer layer is provided with an opening at the first gap, and a moisture intrusion path extending from the bend area to the display area can be blocked, thereby preventing moisture from extending to the display area through the spacer layer, and ensuring the inorganic encapsulation.

In one embodiment, the orthographic projection of the first boundary on the substrate is located on a side of an orthographic projection of the first gap on the substrate away from the display area. With such an arrangement, the first boundary can avoid a weak area, i.e., the region where the first gap is located, thus avoiding the situation in which the first signal line is likely to be corroded by ions overflowing from the first boundary of the polarizer when the first boundary is opposite to the first gap.

In one embodiment, at least two dams are provided, which are arranged in a direction away from the display area, and a second gap is provided between adjacent dams. The inorganic protective layer located in the second gap is in contact with the first signal line. There is no spacer layer at the second gap, or the spacer layer is provided with an opening at the second gap, and a moisture intrusion path extending from the bend area to the display area can be blocked, thereby preventing moisture from extending to the display area through the spacer layer, and ensuring the inorganic encapsulation.

In one embodiment, the orthographic projection of the first boundary on the substrate is located on a side of an orthographic projection of the second gap on the substrate away from the display area.

In one embodiment, the inorganic protective layer is located on a side of the dam away from the substrate, and the orthographic projection of the dam on the substrate overlaps with an orthographic projection of the inorganic protective layer on the substrate.

In one embodiment, there is a notch in a sidewall of a portion of the first signal line that is located in the first gap, and a sidewall of the portion of the first signal line that is covered by the spacer layer has a higher flatness than the sidewall of the portion of the first signal line that is located in the first gap. Due to the protection of the spacer layer, the sidewall of the portion of the first signal line that is covered by the spacer layer will not be corroded by an etching solution in a subsequent etching process (e.g., an anode patterning process), and accordingly the sidewall of the portion of the first signal line that is covered by the spacer layer will not be corroded. The portion of the first signal line located in the first gap is not protected by the spacer layer, the sidewall of the portion of the first signal line that is located in the first gap is corroded, and the presence of the notch results in that the inorganic protective layer on the sidewall of the portion of the first signal line that is located in the first gap is thin and the inorganic protective layer on the sidewall of the portion of the first signal line that is covered by the spacer layer is thick, and the inorganic protective layer on the sidewall of the portion of the first signal line that is located in the first gap is likely to be damaged by the ions overflowing from the first boundary of the polarizer, while the inorganic protective layer above the portion of the first signal line that is covered by the spacer layer is less likely to be damaged by the ions overflowing from the first boundary of the polarizer, that is, the region where the first gap is located is a weak area.

In one embodiment, a minimum thickness of the inorganic protective layer between the portion of the first signal line that is covered by the spacer layer and the first boundary is greater than a minimum thickness of the inorganic protective layer corresponding to the sidewall of the portion of the first signal line that is located in the first gap.

In one embodiment, the first signal line includes a first titanium metal layer, an aluminum metal layer, and a second titanium metal layer which are stacked sequentially in a thickness direction of the substrate.

In one embodiment, at least a portion of the at least one dam and the spacer layer are disposed in the same layer.

In one embodiment of the disclosure, the display module further includes a first inorganic encapsulation layer and/or a pixel defining layer. In the non-display area, at least a portion of the first inorganic encapsulation layer is used as at least a portion of the inorganic protective layer, and/or at least a portion of the pixel defining layer is used as at least a portion of the inorganic protective layer.

In one embodiment, in the non-display area, the spacer layer includes a third boundary, the pixel defining layer includes a fifth boundary, and an orthographic projection of the fifth boundary on the substrate is located on a side of an orthographic projection of the third boundary on the substrate away from the display area.

In one embodiment, in the non-display area, the first inorganic encapsulation layer includes a sixth boundary, and an orthographic projection of the sixth boundary on the substrate is located on the side of the orthographic projection of the third boundary on the substrate away from the display area.

In one embodiment, in the non-display area, the orthographic projection of the fifth boundary of the pixel defining layer on the substrate is located on a side of the orthographic projection of the sixth boundary of the first inorganic encapsulation layer on the substrate close to the display area.

In one embodiment, in the non-display area, the orthographic projection of the fifth boundary of the pixel defining layer on the substrate is located on a side of the orthographic projection of the first boundary on the substrate close to the display area.

In one embodiment, in the non-display area, a distance between the orthographic projection of the fifth boundary of the pixel defining layer on the substrate and the orthographic projection of the first boundary on the substrate is greater than or equal to 30 μm and less than or equal to 120 μm. In this way, the coverage area of the pixel defining layer on the spacer layer can be ensured to improve the ion blocking effect, and a space can also be reserved for the other film layers in the inorganic protective layer to wrap around the boundary of the pixel defining layer, to avoid that the edge of the inorganic protective layer extends too far to be detrimental to the extremely narrow border design of the display module.

In one embodiment, in the non-display area, the orthographic projection of the sixth boundary of the first inorganic encapsulation layer on the substrate is located on the side of the orthographic projection of the first boundary on the substrate close to the display area.

In one embodiment, in the non-display area, a distance between the orthographic projection of the sixth boundary of the first inorganic encapsulation layer on the substrate and the orthographic projection of the first boundary on the substrate is greater than or equal to 5 μm and less than or equal to 95 μm. In this way, the coverage area of the first inorganic encapsulation layer on the spacer layer can be ensured to improve the ion blocking effect, and a space can also be reserved for the other film layers in the inorganic protective layer to wrap around the boundary of the first inorganic encapsulation layer, to avoid that the edge of the inorganic protective layer extends too far to be detrimental to the extremely narrow border design of the display module.

In one embodiment, in the non-display area, the first inorganic encapsulation layer is in contact with the pixel defining layer.

In one embodiment, the thickness of the pixel defining layer is less than the thickness of the first inorganic encapsulation layer.

In the above embodiments, the first boundary of the polarizer and the first signal line are spaced apart by both the first inorganic encapsulation layer and the pixel defining layer, thereby further improving the effect of intercepting ions to further reduce the risk of corrosion of the first signal line.

In one embodiment of the disclosure, the display module may further include a second signal line located in the non-display area and between the spacer layer and the substrate. The spacer layer is provided with a via hole in the non-display area, and an orthographic projection of the via hole on the substrate overlaps with an orthographic projection of a portion of the second signal line on the substrate.

In one embodiment, the orthographic projection of the first boundary on the substrate is located between the display area and the orthographic projection of the via hole on the substrate.

In one embodiment, a distance between the orthographic projection of the first boundary on the substrate and the orthographic projection of the via hole on the substrate in a direction perpendicular to the first boundary or away from the display area is greater than or equal to 0.09 mm.

In one embodiment, the second signal line and the first signal line are disposed in the same layer and made of the same material.

In one embodiment, the first signal line is a power line and the second signal line is a touch trace.

In one embodiment, the display panel further includes a bend area, and the via hole is located between the display area and the bend area.

In one embodiment, the display panel further includes a binding area on a side of the bend area away from the display area.

In one embodiment of the disclosure, in the non-display area, the inorganic protective layer includes a second boundary, and an orthographic projection of the second boundary on the substrate is located between the display area and the orthographic projection of the via hole on the substrate.

In one embodiment, a distance between the orthographic projection of the second boundary of the inorganic protective layer on the substrate and the orthographic projection of the via hole on the substrate is greater than or equal to 0.09 mm.

In one embodiment, the distance of the orthographic projection of the second boundary of the inorganic protective layer on the substrate and the orthographic projection of the via hole on the substrate is greater than or equal to the sum of an attachment tolerance and an alignment tolerance of the polarizer. In this way, the risk that ions overflowing from the polarizer intrude into the via hole to corrode the second signal line can be reduced.

In one embodiment of the disclosure, the display module further includes a third signal line. The third signal line is electrically connected to the second signal line through the via hole, and the third signal line is located between the inorganic protective layer and the polarizer.

In one embodiment, the display module may further include a touch functional layer including a touch electrode, the touch electrode being electrically connected to the third signal line and located in the display area.

In one embodiment, the third signal line extends into the via hole along the first inorganic encapsulation layer to be electrically connected to the second signal line.

In one embodiment, the third signal line and at least a portion of the touch electrode are disposed in the same layer and made of the same material.

In one embodiment of the disclosure, the touch functional layer includes at least two conductive layers and an inorganic insulating layer located between the conductive layers, and at least a portion of the inorganic insulating layer is used as at least a portion of the inorganic protective layer in the non-display area.

In one embodiment, in the non-display area, the spacer layer includes a third boundary, the inorganic insulating layer includes an eighth boundary, and an orthographic projection of the eighth boundary on the substrate is located on a side of the orthographic projection of the first boundary and/or the third boundary on the substrate away from the display area.

In one embodiment, at least a portion of the eighth boundary of the inorganic insulating layer located in the non-display area is the second boundary.

In one embodiment, the display module further includes a first inorganic encapsulation layer located between the touch functional layer and the substrate.

In one embodiment, the display module further includes a touch buffer layer located between the first inorganic encapsulation layer and the touch functional layer and covering the display area and extending to the non-display area; and in the non-display area, at least a portion of the touch buffer layer is used as at least a portion of the inorganic protective layer.

In one embodiment, in the non-display area, the touch buffer layer includes a seventh boundary, and an orthographic projection of the seventh boundary on the substrate is located on the side of the orthographic projection of the first boundary and/or the third boundary on the substrate away from the display area.

In one embodiment, in the non-display area, an orthographic projection of a sixth boundary of the first inorganic encapsulation layer on the substrate is located on a side of an orthographic projection of a boundary of the touch buffer layer on the substrate close to the display area, and at least a portion of the seventh boundary of the touch buffer layer in the non-display area is the second boundary.

In one embodiment of the disclosure, the thickness of the spacer layer is greater than or equal to 1.8 μm and less than or equal to 2.4 μm, and/or the spacer layer is an organic layer. The spacer layer can have a sufficient thickness within this value range to ensure the effect of spacing the inorganic protective layer apart from the first signal line. And/or, the risk of etching the sidewall of the first signal line that is covered by the spacer layer can be reduced.

In one embodiment, the display module further includes a light-emitting device layer and a flat layer, the light-emitting device layer being located in the display area and comprising a plurality of light-emitting devices, and the flat layer being located between the light-emitting device layer and the substrate.

In one embodiment, the spacer layer and the flat layer are disposed in the same layer and made of the same material. In this way, the arrangement of the spacer layer does not need an additional preparation process of the display module, thereby facilitating the control of the preparation cost of the display module.

In one embodiment of the disclosure, the display module may further include at least one dam located in the non-display area, one of the at least one dam is the spacer layer, and an overlap region between the orthographic projection of the first signal line on the substrate and an orthographic projection of the dam on the substrate overlaps with the orthographic projection of the first boundary on the substrate.

In the above embodiment, the dam is used directly as the spacer layer without the need for an additional preparation process of the display module, thereby facilitating the control of the preparation cost of the display module; and the size of the non-display area will not be increased additionally, thereby facilitating the control of the design size of the display module.

In one embodiment, an overlap region between the orthographic projection of the first signal line on the substrate and an orthographic projection of the dam that is furthest from the display area on the substrate overlaps with the orthographic projection of the first boundary on the substrate.

In one embodiment, the dam farthest from the display area is the spacer layer.

In one embodiment, orthographic projections of all of the dams on the substrate are located within an orthographic projection of the inorganic protective layer on the substrate.

In one embodiment of the disclosure, with respect to the dam (which serves as the spacer layer) of which the orthographic projection on the substrate overlaps with the orthographic projection of the first boundary on the substrate, the width of the dam is greater than or equal to 0.09 mm in a direction from the display area to the non-display area.

In one embodiment, with respect to the dam (which serves as the spacer layer) of which the orthographic projection on the substrate overlaps with the orthographic projection of the first boundary on the substrate, the width of the dam is greater than or equal to the sum of an attachment tolerance and an alignment tolerance of the polarizer in the direction from the display area to the non-display area.

In the above embodiment, in consideration of the width of the spacer layer (the dam serving as the spacer layer), the attachment tolerance and the alignment tolerance are taken into account, and in the actual process, even if the position of the polarizer is shifted, the edge of the polarizer and the first signal line can be spaced apart by the spacer layer, thus ensuring the yield of the display module in the actual production process.

In one embodiment of the disclosure, the display module may further include a light-emitting device layer and an isolation structure. The light-emitting device layer is located in the display area and includes a plurality of light-emitting devices, the isolation structure is located on the substrate and provided with a plurality of isolation openings, and at least a portion of each light-emitting device is located in a corresponding isolation opening.

In the above embodiment, the light-emitting devices that emit light in different colors are prepared separately by means of the isolation structure, and the thicknesses of film layers in the light-emitting devices are controlled accurately to improve the light-emitting efficiency of the light-emitting devices. In addition, the light-emitting devices are prepared based on the isolation structure, at least some of the film layers in the light-emitting devices may be prepared using an open mask or without a mask, and the positions of the light-emitting devices are controlled accurately, and accordingly, the gap between the light-emitting devices may be greatly reduced, thereby increasing the pixels-per-inch PPI of the display module.

In one embodiment, an orthographic projection, on the substrate, of the end of the isolation structure facing away from the substrate is located within an orthographic projection, on the substrate, of the end of the isolation structure facing toward the substrate.

In one embodiment of the disclosure, the display module may further include a pixel defining layer. The pixel defining layer is located on the substrate and is provided with pixel openings, the pixel openings being in communication with corresponding isolation openings.

In one embodiment, the pixel defining layer is located between the substrate and the isolation structure. A plurality of pixel openings corresponding to the isolation openings are defined from the pixel openings. An orthographic projection of the pixel opening on the substrate is located within an orthographic projection of the corresponding isolation opening on the substrate.

In one embodiment, the pixel defining layer is an inorganic film layer.

In one embodiment, in the non-display area, at least a portion of the pixel defining layer is used as at least a portion of the inorganic protective layer.

In one embodiment, the pixel defining layer covers the display area and extends to the non-display area, and in the non-display area, the orthographic projection of the first boundary of the polarizer on the substrate coincides with an orthographic projection of a fifth boundary of the pixel defining layer on the substrate; or in the non-display area, the orthographic projection of the first boundary of the polarizer on the substrate is located on a side of the orthographic projection of the fifth boundary of the pixel defining layer on the substrate away from the display area.

In one embodiment of the disclosure, the isolation structure includes a support and a crown on a side of the support facing away from the substrate, and an orthographic projection of the support on the substrate is located within an orthographic projection of the crown on the substrate.

In one embodiment of the disclosure, the light-emitting device includes a first electrode, a light-emitting unit and a second electrode which are stacked sequentially on the substrate in a direction away from the substrate. The light-emitting unit and the second electrode of each of the light-emitting devices are located in the corresponding isolation opening.

In one embodiment, the second electrode is electrically connected to the first signal line.

In one embodiment, the support is a conductive structure and the second electrode is electrically connected to a sidewall of the support.

In one embodiment, the pixel defining layer includes a pixel define portion located on a side of the first electrode away from the substrate and covering an edge of the first electrode, and the first electrode is exposed from the pixel opening.

In one embodiment of the disclosure, the isolation structure may further include an auxiliary support located between the support and the substrate. The orthographic projection of the support on the substrate is located within an orthographic projection of the auxiliary support on the substrate.

In one embodiment, the auxiliary support is a conductive structure, and the second electrode of the light-emitting device is electrically connected to the auxiliary support.

In one embodiment, the orthographic projection of the auxiliary support is located within the orthographic projection of the crown on the substrate.

In one embodiment, the auxiliary support is located between the support and the pixel defining layer.

In one embodiment of the disclosure, the display module may further include a second inorganic encapsulation layer located on a side of the light-emitting device away from the substrate. The second inorganic encapsulation layer includes a plurality of encapsulation units which are spaced apart from each other and which correspond to the isolation openings, the encapsulation units covering the light-emitting devices confined by the corresponding isolation openings, and in the non-display area, the orthographic projection of the spacer layer on the substrate does not overlap with an orthographic projection of the second inorganic encapsulation layer on the substrate.

In one embodiment, the thickness of the pixel defining layer is less than the thickness of the second inorganic encapsulation layer.

In one embodiment, the display module further includes a first inorganic encapsulation layer located on a side of the second inorganic encapsulation layer away from the substrate, and in the non-display area, at least a portion of the first inorganic encapsulation layer is used as at least a portion of the inorganic protective layer.

In one embodiment, the thickness of the pixel defining layer is less than the thickness of the first inorganic encapsulation layer.

In one embodiment, the display module further includes a third encapsulation layer located between the first inorganic encapsulation layer and the second inorganic encapsulation layer.

In one embodiment, the third encapsulation layer is an organic layer.

In one embodiment, the display module further includes at least one dam located in the non-display area, and the third encapsulation layer is located on a side of the at least one dam close to the display area.

In one embodiment, the display module further includes a light-emitting device layer located in the display area and including a plurality of light-emitting devices. The light-emitting device includes a first electrode, at least one light-emitting unit and a second electrode which are stacked sequentially on the substrate in a direction away from the substrate. The second electrode is electrically connected to the first signal line.

In one embodiment, the light-emitting device includes at least two light-emitting units stacked in a thickness direction of the substrate.

In one embodiment, the plurality of light-emitting devices are classified as light-emitting devices that emit light in various colors respectively, and the encapsulation units corresponding to the light-emitting devices that are adjacent to each other and emit light in different colors respectively are spaced apart from each other.

In one embodiment, each of the light-emitting devices includes at least two light-emitting units stacked in the thickness direction of the substrate. Where the light-emitting device includes a plurality of light-emitting units (i.e., a laminated light-emitting device), the light-emitting device can have a higher light-emitting efficiency, but the second electrode has a lower voltage (a higher negative voltage). Where the first signal line is connected to the second electrode, the first signal line will also apply a lower voltage, which results in a more severe attraction effect on potassium ions. This problem can be improved significantly by using the embodiments of the present application.

In one embodiment, the encapsulation units extend to a side of the isolation structure facing away from the substrate; and between the light-emitting devices that are adjacent to each other and emit light in different colors, the portion of each encapsulation unit that is located at the isolation structure and faces away from the substrate is spaced apart from the isolation structure to form an overhanging portion.

In one embodiment of the disclosure, the polarizer includes a first protective film, a linear polarization layer, and a second protective film which are stacked sequentially in a direction away from the substrate.

In one embodiment, the first protective film includes a triacetate film layer, and the linear polarization layer includes a polyvinyl alcohol film layer; and the second protective film includes a triacetate film layer.

In one embodiment of the disclosure, the first signal line is a power line or a direct-current potential line.

In one embodiment, the first signal line is a metal trace.

In one embodiment, the display module further includes a pixel drive circuit and/or a scanning circuit, and the first signal line is electrically connected to the pixel drive circuit or the scanning circuit.

In one embodiment, the non-display area of the display module further includes a bend area; and the orthographic projection of the first boundary on the substrate is located between the display area and the bend area.

In one embodiment, a distance between the orthographic projection of the first boundary on the substrate and the bend area is greater than or equal to 160 μm and less than or equal to 250 μm. In this way, a sufficient distance can be ensured between the bend area and the inorganic protective layer to avoid cracking of the inorganic protective layer when the bend area is bent.

In one embodiment, the non-display area of the display module further includes a binding area located on a side of the bend area away from the display area, the binding area being provided with a binding pin to which the first signal line is electrically connected.

In one embodiment, the display module further includes a filling layer located between the polarizer and the first inorganic encapsulation layer to fill a gap between the polarizer and the first inorganic encapsulation layer.

In one embodiment, in the non-display area, the filling layer includes a fourth boundary, and an orthographic projection of the fourth boundary on the substrate is located on a side of the orthographic projection of the first boundary on the substrate away from the display area.

In one embodiment, the filling layer is an optical adhesive layer.

One embodiment of the disclosure provides a display device, including the display module in the embodiments described above.

### BRIEF DESCRIPTION OF THE DRAWINGS

FIG. 1 is a schematic view of a planar structure of a display module according to an embodiment of the disclosure.

FIG. 2 is an enlarged view of a region S1 within a display area of the display module shown in FIG. 1.

FIG. 3A is a sectional view of the display module shown in FIG. 2 along M1-N1 in one design.

FIG. 3B is a sectional view of the display module shown in FIG. 1 along M2-N2 in one design.

FIG. 3C is a schematic sectional view of part of the structure of the display module shown in FIG. 3B in a region P1.

FIG. 3D is a schematic sectional view of part of the structure of the display module shown in FIG. 3B in a region where a spacer layer is located.

FIG. 3E is a schematic sectional view of a structure of a polarizer of the display module shown in FIG. 1.

FIG. 4 is a sectional view of the display module shown in FIG. 1 along M2-N2 in an alternative design.

FIG. 5A is a sectional view of the display module shown in FIG. 2 along M1-N1 in an alternative design.

FIG. 5B is a sectional view of the display module shown in FIG. 1 along M2-N2 in an alternative design.

FIG. 5C is a schematic view of a planar structure of another display module according to an embodiment of the disclosure.

FIG. 5D is a sectional view of the display module shown in FIG. 5C along M3-N3 in one design.

FIG. 6A is a sectional view of the display module shown in FIG. 2 along M1-N1 in an alternative design.

FIG. 6B is a sectional view of the display module shown in FIG. 1 along M2-N2 in an alternative design.

FIG. 6C is a sectional view of the display module shown in FIG. 5C along M3-N3 in an alternative design.

FIG. 6D is a sectional view of the display module shown in FIG. 1 along M2-N2 in an alternative design.

FIG. 6E is a sectional view of the display module shown in FIG. 5C along M3-N3 in an alternative design.

FIG. 7A is a sectional view of the display module shown in FIG. 2 along M1-N1 in an alternative design.

FIG. 7B is a sectional view of the display module shown in FIG. 1 along M2-N2 in an alternative design.

FIGS. 8 to 12 are process diagrams of a method for preparing the display module shown in FIGS. 5A and 5B according to an embodiment of the disclosure.

### LIST OF REFERENCE SIGNS

10—display module; 11a—display area; 11b—binding area; 11c—non-display area; 12—border area; 20—inorganic protective layer; 100—substrate; 100a—drive circuit layer; 111—first signal line; 112—second signal line; 113—third signal line; 120—flat layer; 200—light-emitting device; 210—first electrode; 220—light-emitting unit; 221—first functional layer; 222—light-emitting layer; 223—second functional layer; 230—second electrode; 300—isolation structure; 301—isolation opening; 302—pixel opening; 310—support; 320—crown; 330—pixel defining layer; 340—auxiliary support; 350—dam; 400—spacer layer; 510—first inorganic encapsulation layer; 520—second inorganic encapsulation layer; 520a—encapsulation film; 521—encapsulation unit; 530—third encapsulation layer; 540—touch buffer layer; 550—inorganic insulating layer; 600—polarizer; 700—filling layer; 800—touch functional layer; 810—first conductive layer; 820—second conductive layer; 900—photoresist pattern.

### DETAILED DESCRIPTION OF EMBODIMENTS

The embodiments of the specification will be clearly and completely described below in conjunction with the accompanying drawings in the embodiments of the specification. Apparently, the embodiments described are merely some rather than all of the embodiments of the specification. All other embodiments in the art on the basis of the embodiments in the specification fall within the scope of protection of the specification.

It should be noted that the terms “first”, “second” and the like in the specification, the claims and the accompanying drawings of the present disclosure are used to distinguish similar objects, and are not necessarily used to describe a specific order or sequence. It should be understood that the data termed in such a way are interchangeable in proper circumstances, and this embodiment of the present disclosure described herein can be implemented in other orders than the order illustrated or described herein. In addition, the terms “include” and “have”, and any variations thereof, are intended to cover non-exclusive inclusion, for example, a process, method, system, product, or device including a series of steps or units is not necessarily limited to those steps or units explicitly listed, and may include other steps or units not explicitly listed or inherent to the process, method, product, or apparatus.

A polarizer is provided on a light exit side of a display module to ensure the display effect of the display module, but ions (e.g., potassium ions and iodine ions) will overflow from an edge of the polarizer. The edge of the polarizer corresponds to a circuit area (e.g., including a non-display area as described below) on the periphery of the display module, and a signal line in the circuit area creates an electric field, to guide the ions overflowing from the polarizer to move toward the signal line.

An inorganic layer (e.g., a first inorganic encapsulation layer as described below) is provided in the display module. The inorganic layer extends into the circuit area to cover the signal line. The ions moving toward the signal line under the guide of the electric field are intercepted by the inorganic layer and accumulated on the inorganic layer, but the accumulated ions will damage the encapsulation effect of the inorganic layer. If the inorganic layer is close to the signal line or in direct contact with the signal line, the ions accumulated on the inorganic layer will further intrude into the signal line, causing the corrosion damage to the signal line or encapsulation failure, and leading to corrosion of the signal line caused by external water and oxygen.

Embodiments of the disclosure provide a display module and a display device, to solve at least the above problems. The display module includes a display area and a non-display area. The display module includes a substrate, and a first signal line, an inorganic protective layer, a spacer layer, and a polarizer which are disposed on the substrate. The first signal line is located on the substrate. The inorganic protective layer is located at least in the non-display area and on a side of the first signal line away from the substrate, the spacer layer is located at least in the non-display area and between the inorganic protective layer and the substrate, and the polarizer is located on a side of the inorganic protective layer facing away from the substrate and covers the display area and extends to the non-display area. In the non-display area, the polarizer includes a first boundary, and an overlap region between an orthographic projection of the first signal line on the substrate and an orthographic projection of the spacer layer on the substrate overlaps with an orthographic projection of the first boundary on the substrate. Thus, in the non-display area, an orthographic projection of an edge (the first boundary) of the polarizer on the substrate is within the orthographic projection of the spacer layer on the substrate. Ions overflowing from an edge of the polarizer will be accumulated on the inorganic protective layer and damage the structure of the inorganic protective layer when moving toward the first signal line; and the inorganic protective layer and the first signal line are separated by the spacer layer in the vicinity of the edge of the polarizer, and the distance between the first signal line and the inorganic protective layer is increased. Therefore, even if the ions are accumulated on the inorganic protective layer, it is difficult for the accumulated ions to further intrude into the first signal line (the ions are accumulated in the vicinity of the region where the inorganic protective layer is located), thereby avoiding damage to the first signal line due to corrosion by the ions, or avoiding the encapsulation failure, which otherwise leads to corrosion of the first signal line caused by external water and oxygen, to ensure functions of the display module.

The structure of the display module according to at least one embodiment of the disclosure will be described in detail below with reference to the drawings. In addition, in these drawings, a spatial rectangular coordinate system is established with the substrate as a reference to more intuitively present the positional relationship of the relevant structures in the display module. In the spatial rectangular coordinate system, an X-axis and a Y-axis are parallel to the plane where the substrate is located, and a Z-axis is perpendicular to the plane where the substrate is located.

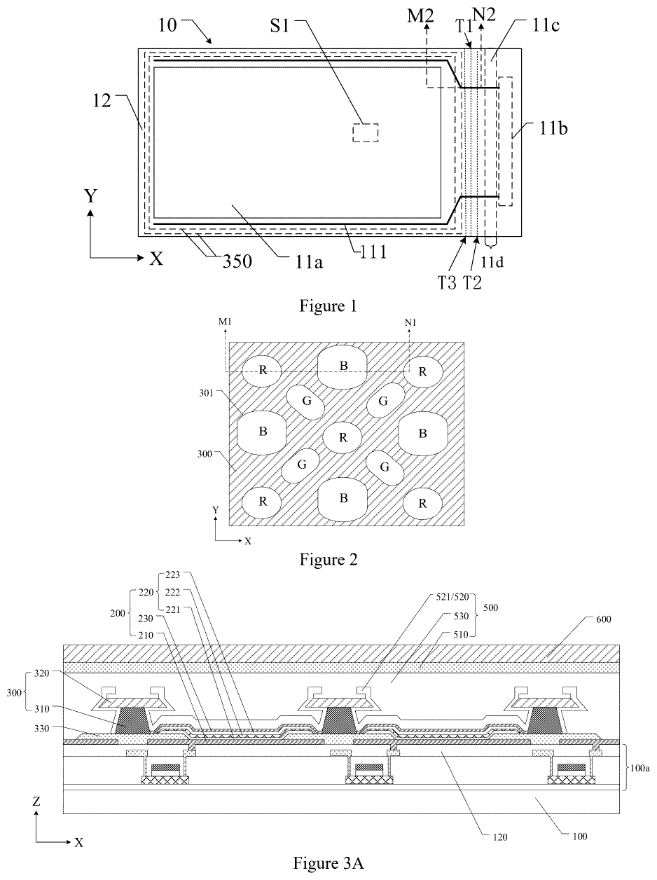

As shown in FIGS. 1, 2, 3A and 3B, a planar region of the display module 10 may be divided into a display area 11a and a border area 12 surrounding at least part of the display area 11a. The border area 12 includes a non-display area 11c. There may be sub-pixels (which may be referred to as subpixels) arranged in the display area 11a, such as sub-pixels R, G, B, and physical structures of the sub-pixels may be light-emitting devices. Sub-pixels that are adjacent to each other and have different colors of emergent light constitute a pixel (which may be referred to as a pixel unit, a large pixel, etc.). The density of the pixels arranged in the display area 11a represents the pixels-per-inch PPI. Signal lines used for driving the sub-pixels to emit light are gathered in the non-display area 11c to be connected to other control circuits.

It should be noted that the border area 12 is not limited to completely surrounding the display area 11a, and in some embodiments of the disclosure, part of a trace in the border area 12 may be routed into the display area 11a, and the border area 12 may be designed as a single-sided border. The physical structure of the display module 10 may include a substrate 100, and a first signal line 111, an inorganic protective layer 20, a spacer layer 400 and a polarizer 600 which are disposed on the substrate 100.

For example, the inorganic protective layer 20 may include a first inorganic encapsulation layer 510. The first inorganic encapsulation layer 510 covers the display area 11a and extends to the non-display area 11c. The first inorganic encapsulation layer 510 is used for encapsulating the entire display module. In the non-display area, the first inorganic encapsulation layer 510 may be configured to cover the first signal line 111 in order to ensure its encapsulation effect. It should be noted that the inorganic protective layer 20 is not limited to including the first inorganic encapsulation layer 510, and may be designed according to actual requirements.

In the following embodiments, in order to briefly describe the principles of the embodiments of the present application, several arrangements of the inorganic protective layer 20 are described in an example of the inorganic protective layer 20 including the first inorganic encapsulation layer 510.

The first signal line 111 may be located in the non-display area 11c only, or extend from the display area 11a to the non-display area 11c. The inorganic protective layer 20 (e.g., including the first inorganic encapsulation layer 510) covers the display area 11a and extends to the non-display area 11c. The spacer layer 400 is located in the non-display area 11c and between the inorganic protective layer 20 (e.g., the first inorganic encapsulation layer 510 included therein) and the substrate 100. The polarizer 600 is located on a side of the inorganic protective layer 20 facing away from the substrate 100, and covers the display area 11a and extends to the non-display area 11c. The polarizer 600 includes a first boundary T1. An overlap region between an orthographic projection of the first signal line 111 on the substrate 100 and an orthographic projection of the spacer layer 400 on the substrate 100 overlaps with an orthographic projection of the first boundary T1 on the substrate 100. The spacer layer 400 is required to correspond to an edge (the first boundary T1) of the polarizer 600 such that, at the edge (the first boundary T1) of the polarizer 600, the spacer layer 400 can increase the distance between the inorganic protective layer 20 (e.g., including the first inorganic encapsulation layer 510) and the first signal line 111. That is, in the non-display area 11c, an orthographic projection of the edge (the first boundary T1) of the polarizer 600 on the substrate 100 is located within the orthographic projection of the spacer layer 400 on the substrate 100, and the orthographic projection of the edge (the first boundary T1) of the polarizer 600 on the substrate 100 is located within an orthographic projection of the inorganic protective layer 20 (e.g., including the first inorganic encapsulation layer 510) on the substrate 100.

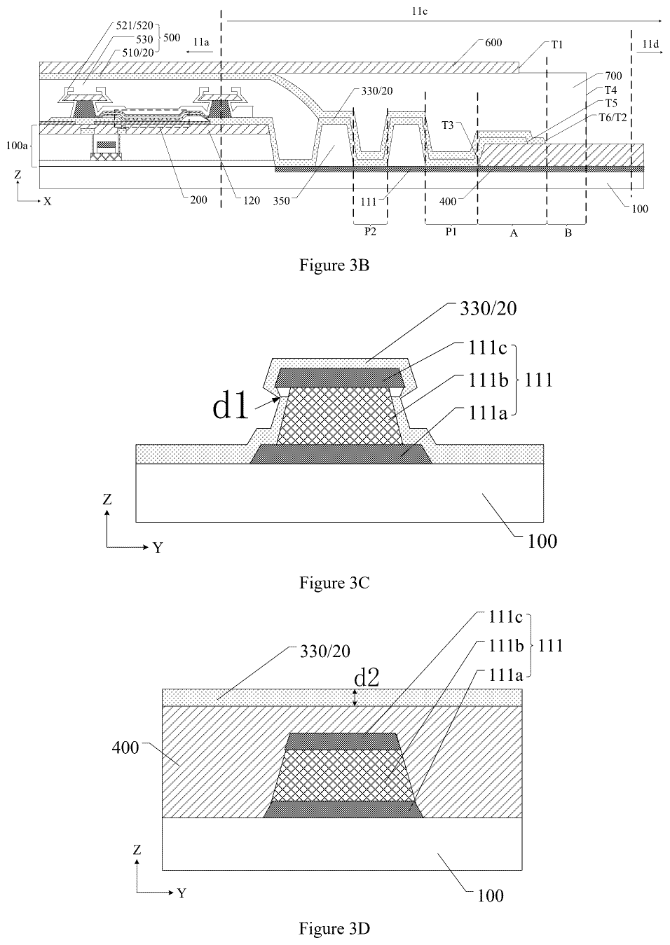

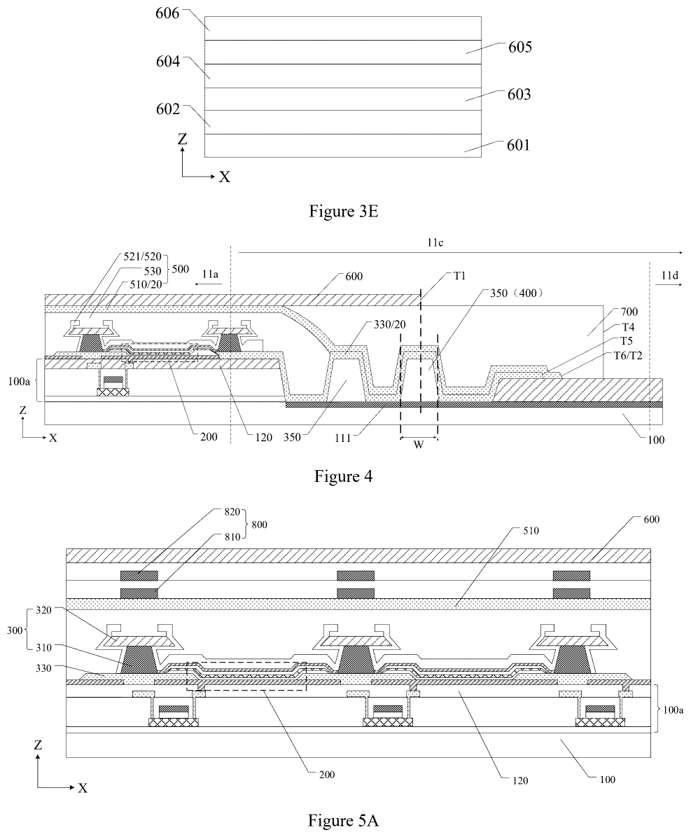

In at least one embodiment of the disclosure, as shown in FIG. 3E, the polarizer includes a first protective film, a linear polarization layer PVA, and a second protective film which are stacked sequentially in a direction away from the substrate. In one embodiment, the first protective film includes a triacetate film layer. In one embodiment, the linear polarization layer PVA includes a polyvinyl alcohol film layer. In one embodiment, the second protective film includes a triacetate film layer. The polarizer may include a first protective film, a polyvinyl alcohol film layer and a second protective film which are stacked sequentially in the direction away from the substrate. The first protective film and the second protective film may block ions in the polyvinyl alcohol film layer. The polarizer may further include a quarter-wave plate. Specifically, the polarizer may include a pressure-sensitive adhesive 601, a quarter-wave plate (or referred to as a ¼ compensation film) 602, a pressure-sensitive adhesive 603, a TAC layer (a triacetate film layer) 604, a PVA (polyvinyl alcohol) film layer 605, and an HC-TAC layer 606 (a hardness layer, which plays a role in support and protection) that are stacked in sequence. The PVA film layer 605 contains ions such as potassium ions and iodine ions, the TAC layer 604 and the HC-TAC layer 606 on two sides of the PVA film layer 605 may be a first protective film and a second protective film, respectively, and the TAC layer 604 and the HC-TAC layer 606 may block these ions such that these ions can only overflow from the edge of the polarizer. It should be noted that the polarizer may further include other functional film layers. This is not limited in the embodiments of the disclosure, and may be designed according to actual process requirements.

In an embodiment of the disclosure, there is no limitation on the type of the first signal line 111, which may be a power line, a reset line, a gate scanning signal line, etc. Alternatively, the first signal line 111 may be a direct-current signal line.

For example, as shown in FIG. 3B, the first signal line 111 may be a power line (which may be referred to as a common electrode line, or ELVSS). The power line, when driven, may have a constant negative voltage (e.g., approximately −3 V, or lower, e.g., less than −5.4 V at a brightness of 600 nit) to create an electric field around the power line, and potassium ions overflowing from the edge of the polarizer 600 move toward the power line under the action of the electric field. For example, the first signal line 111 may be a direct-current potential line or another signal line having a constant potential (not limited to a constant potential, which may be a constant negative voltage or a constant positive voltage).

In at least one embodiment of the disclosure, as shown in FIG. 1, the non-display area 11c may further include a binding area 11b. The binding area 11b may be provided with a binding pin (which may be referred to as a bonding pad, or PAD), and a signal line (including the first signal line 111) in a conductor layer may be gathered and then extend to the binding area 11b to be connected to the bonding pin correspondingly. The binding pin may be used for connecting an external control circuit and/or chip, etc.

In at least one embodiment of the disclosure, as shown in FIG. 1, the non-display area 11c may include a bend area 11d located between the binding area 11b and the display area 11a. By bending the bend area, the binding area may be disposed on the back of the substrate to reduce the width of the border. The substrate may be a flexible substrate or a rigid substrate.

For example, the non-display area of the display module further includes a bend area 11d. In one embodiment, the orthographic projection of the first boundary T1 on the substrate is located between the display area and the bend area. For example, a distance D5 between the orthographic projection of the first boundary T1 on the substrate and the bend area is greater than or equal to 160 μm and less than or equal to 250 μm. The distance D5 may be 205 μm. The distance D5 may be 170 μm, 180 μm, 190 μm, 200 μm, 210 μm, 220 μm, 230 μm, 240 μm, etc. The lower limit of the value range of the distance D5 may be 160 μm, 170 μm, 180 μm, 190 μm, 200 μm, 210 μm, 220 μm, 230 μm, 240 μm, etc. The upper limit of the value range of the distance D5 may be 170 μm, 180 μm, 190 μm, 200 μm, 210 μm, 220 μm, 230 μm, 240 μm, 250 μm, etc. The upper and lower limits of the value range of the distance D5 may be set as needed, where the upper limit may be greater than the lower limit.

For example, the non-display area of the display module further includes a binding area 11b located on a side of the bend area away from the display area. The binding area 11b is provided with a binding pin to which the first signal line 111 is electrically connected.

In at least one embodiment of the disclosure, as shown in FIG. 3B, the display module further includes a filling layer 700. The filling layer 700 is located between the polarizer 600 and the inorganic protective layer 20 (e.g., including the first inorganic encapsulation layer 510) to fill a gap between the polarizer 600 and the inorganic protective layer 20 (e.g., including the first inorganic encapsulation layer 510), thereby supporting the polarizer 600.

For example, as shown in FIG. 3B, an orthographic projection of a boundary (a fourth boundary T4 in the figure) of the filling layer 700 in the non-display area on the substrate 100 is located on a side of the orthographic projection of the first boundary T1 on the substrate 100 away from the display area 11a, ensuring that the filling layer 700 can support the first boundary T1 of the polarizer 600.

The filling layer 700 may be an organic material layer for filling the gap between the polarizer 600 and the inorganic protective layer 20 (e.g., including the first inorganic encapsulation layer 510). Accordingly, the organic material layer has a poor effect of blocking ions such as potassium ions, and the ions are likely to pass through the filling layer 700 to enter the inorganic protective layer 20 (e.g., including the first inorganic encapsulation layer 510). Therefore, the provision of the spacer layer 400 is particularly necessary for protecting the first signal line 111.

In at least one embodiment of the disclosure, the filling layer 700 is an optical adhesive layer for bonding the edge (the first boundary T1) of the polarizer 600 and a portion close to the edge while flattening the non-display area 11c.

In at least one embodiment of the disclosure, as shown in FIGS. 3A and 3B, the display module includes a drive circuit layer 100a located on the substrate 100. The drive circuit layer 100a includes a plurality of pixel drive circuits located in the display area 11a. For example, the pixel drive circuit may include a plurality of thin film transistors (TFTs), capacitors, etc., which are formed in a variety of forms such as 2T1C (i.e., two thin film transistors (TFTs) and one capacitor (C)), 3T1C, 7T1C, or 8T1C. The first signal line 111 is connected to this pixel drive circuit.

The drive circuit layer 100a may include an inorganic buffer layer, an interlayer insulating layer, a gate insulating layer, a capacitive dielectric layer, a flat layer, and a plurality of conductive layers (e.g., metal layers). The interlayer insulating layer, the capacitive dielectric layer, the gate insulating layer, and the flat layer may all be provided as one or more layers. These film layers may be disposed in the display area and extend to the non-display area. However, these film layers may not be provided in a region of the non-display area that is away from the display area, to increase the flexibility of the non-display area to meet the requirements for bending, etc. It should be noted that the metal layers described above may be used for preparing structures such as capacitors, signal lines, and gate, source and drain electrodes of TFTs.

For example, the first signal line 111 may be a metal trace and thus has a high electrical conductivity to alleviate the problem of voltage drop. Accordingly, there is a greater need for the solution mentioned in the above embodiments due to the fact that a metallic material is more susceptible to ion intrusion.

For example, the display module may further include a scanning circuit. In one embodiment, the first signal line is electrically connected to the pixel drive circuit or the scanning circuit described above. The first signal line may be located in the conductive layer of the drive circuit layer. The first signal line may be located in the conductive layer between the film layer where the first electrode of the light-emitting device is located and the substrate.

In an embodiment of the disclosure, at the edge (the first boundary T1) of the polarizer, the arrangement of the spacer layer is not further limited as long as the spacer layer can separate the inorganic protective layer 20 (e.g., including the first inorganic encapsulation layer) from the first signal line (or the conductor layer). The spacer layer may be provided independently. Alternatively, the spacer layer may be designed according to the original structure in the display module not to complicate the process flow of the display module.

In at least one embodiment of the disclosure, as shown in FIGS. 3A and 3B, in the non-display area, the inorganic protective layer 20 (e.g., the first inorganic encapsulation layer 510 included therein) includes a second boundary T2, and the overlap region between the orthographic projection of the first signal line 111 on the substrate 100 and the orthographic projection of the spacer layer 400 on the substrate 100 overlaps with an orthographic projection of the second boundary T2 on the substrate 100.

In one embodiment, an overlap region between the orthographic projection of the first signal line on the substrate, the orthographic projection of the spacer layer on the substrate and an orthographic projection of the inorganic protective layer on the substrate overlaps with the orthographic projection of the first boundary on the substrate.

In some embodiments of the disclosure, as shown in FIGS. 3A and 3B, the orthographic projection of the first boundary T1 on the substrate 100 is located on a side of the orthographic projection of the second boundary T2 on the substrate 100 close to the display area, thereby expanding the ion blocking range of the inorganic protective layer 20.

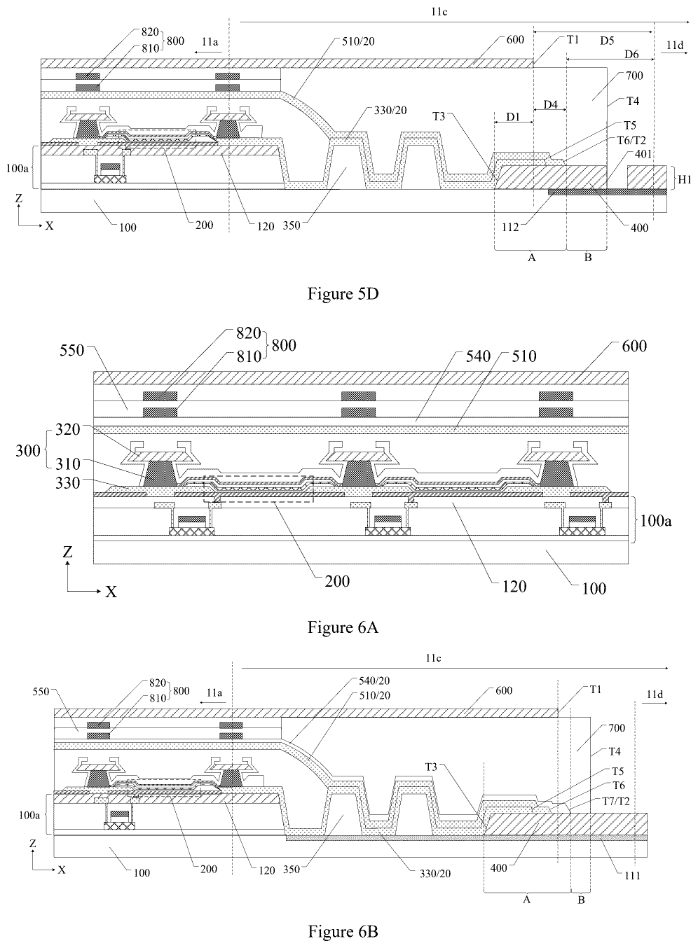

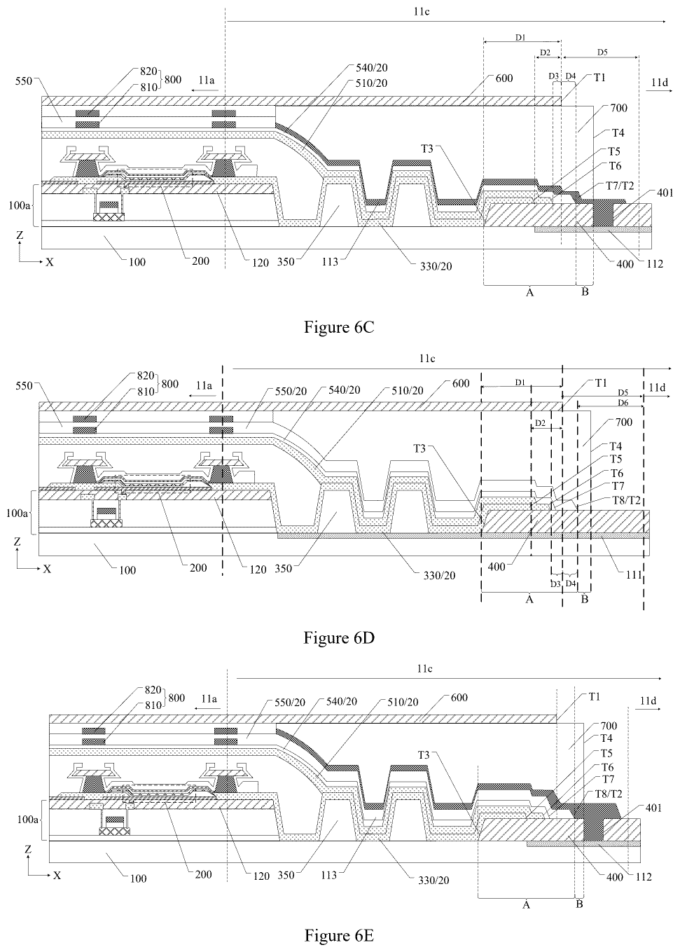

For example, a distance (referring to D4 in FIG. 6C or 6D) between the orthographic projection of the first boundary T1 on the substrate 100 and the orthographic projection of the second boundary T2 on the substrate 100 may be greater than or equal to 130 μm and less than or equal to 220 μm. Within this value range, the ion blocking range of the inorganic protective layer can be guaranteed and the width of a border (e.g., a lower border) of the non-display area will not be additionally increased, which is conducive to the narrow border design of the display module.

For example, further, the distance D4 between the orthographic projection of the first boundary T1 on the substrate 100 and the orthographic projection of the second boundary T2 on the substrate 100 is 175 μm. It should be noted that the value of the distance may be designed according to the needs of the actual process and is not limited to the value range listed here. In one embodiment, the distance D4 may be 140 μm, 150 μm, 160 μm, 170 μm, 180 μm, 190 μm, 200 μm, 210 μm, etc. In one embodiment, the lower limit of the value range of the distance D4 is 130 μm, 140 μm, 150 μm, 160 μm, 170 μm, 180 μm, 190 μm, 200 μm, 210 μm, etc. The upper limit of the value range of the distance D4 is 140 μm, 150 μm, 160 μm, 170 μm, 180 μm, 190 μm, 200 μm, 210 μm, 220 μm, etc. The upper and lower limits of the value range of the distance D4 may be set as needed, where the upper limit may be greater than the lower limit.

In one embodiment, a distance D6 between the orthographic projection of the second boundary T2 on the substrate 100 and the bend area is greater than or equal to 20 μm and less than or equal to 40 μm. The distance D6 may be 30 μm. The lower limit of the value range of the distance D6 is 20 μm, 25 μm, 30 μm, 35 μm, etc. The upper limit of the value range of the distance D6 is 25 μm, 30 μm, or 35 μm, 40 μm, etc. The upper and lower limits of the value range of the distance D6 may be set as needed, where the upper limit may be greater than the lower limit.

In some other embodiments of the disclosure, the orthographic projection of the first boundary T1 on the substrate 100 overlaps and is collinear with the orthographic projection of the second boundary T2 on the substrate 100, i.e., the orthographic projection of the first boundary T1 on the substrate 100 coincides with the orthographic projection of the second boundary T2 on the substrate 100.

In at least one embodiment of the disclosure, as shown in FIGS. 3A and 3B, the spacer layer 400 includes a third boundary T3, and an orthographic projection of the third boundary T3 on the substrate 100 is located on a side of the orthographic projection of the first boundary T1 on the substrate 100 close to the display area.

In one embodiment, the orthographic projection of the third boundary T3 on the substrate 100 is located on the side of the orthographic projection of the second boundary T2 on the substrate 100 close to the display area.

For example, in a direction perpendicular to the second boundary T2 or away from the display area, a distance A between the orthographic projection of the side (e.g., the third boundary T3) of the spacer layer 400 close to the display area on the substrate 100 and the orthographic projection of the second boundary T2 on the substrate 100 is greater than or equal to 0.09 mm.

In at least one embodiment of the disclosure, as shown in FIGS. 3A and 3B, in the non-display area, the distance A between the orthographic projection of the edge (e.g., the third boundary) on the side of the spacer layer 400 facing toward the display area on the substrate 100 and the orthographic projection of an edge of the inorganic protective layer 20 on the substrate 100 is greater than or equal to 0.09 mm.

In at least one embodiment of the disclosure, as shown in FIGS. 3A and 3B, the spacer layer 400 may be provided independently. In the non-display area 11c, the distance A between the orthographic projection of the edge on the side of the spacer layer 400 facing toward the display area on the substrate 100 and the orthographic projection of the edge of the inorganic protective layer 20 on the substrate 100 is greater than or equal to the sum of an attachment tolerance and an alignment tolerance of the polarizer 600. In consideration of the lateral positions of the edge of the spacer layer 400 and the edge (the second boundary T2) of the inorganic protective layer 20, i.e., the distance therebetween in a direction parallel to the plane where the substrate 100 is located, the attachment tolerance and the alignment tolerance in the process of bonding the polarizer 600 are considered to ensure that the inorganic protective layer 20 and the spacer layer 400 will be present in the vicinity of the first boundary of the polarizer 600, ensuring that the edge of the polarizer 600 and the first signal line 111 can still be separated by the spacer layer 400 to ensure the yield of the display module in the actual production process.

It should be noted that, when bonding the polarizer to the light exit side of the display module using an apparatus, it is necessary to align the polarizer with the display module before the bonding process is carried out. There may be errors in alignment in the two processes, i.e. an “alignment tolerance”, which is an accuracy error in alignment of the polarizer with the display module before the polarizer is bonded to the display module by the apparatus; and an “attachment tolerance”, which is a process error when the polarizer is bonded to the display module by the apparatus.

For example, in at least some embodiments of the disclosure, the “alignment tolerance” is approximately 0.01 mm; and the “attachment tolerance” is approximately 0.08 mm. It should be noted that the specific value ranges of the “alignment tolerance” and the “attachment tolerance” may be designed with reference to the attachment process of the polarizer and the accuracy of the apparatus used, and are not limited to the above value ranges.

In one embodiment, the orthographic projection of the second boundary T2 on the substrate is located between the display area and the bend area.

For example, in at least some embodiments of the disclosure, in the non-display area, a distance D1 between the orthographic projection of the third boundary T3 on the substrate 100 and the orthographic projection of the first boundary T1 on the substrate 100 is greater than or equal to 80 μm and less than or equal to 170 μm. In this way, the coverage of a portion of the spacer layer that is used for spacing the polarizer 600 apart from the first signal line 111 can be guaranteed, to ensure that the ions accumulated on the inorganic protective layer 20 will not further intrude into the first signal line 111. The polarizer 600 is far enough away from the weak area, and the influence on the width of the border is reduced. It should be noted that value range of this distance may be designed according to the needs of the actual process and is not limited to the value range listed here. In one embodiment, the distance D1 is 125 μm. In one embodiment, the distance D1 may be 90 μm, 100 μm, 110 μm, 120 μm, 130 μm, 140 μm, 150 μm, 160 μm, etc. In one embodiment, the lower limit of the value range of the distance D1 is 80 μm, 90 μm, 100 μm, 110 μm, 120 μm, 130 μm, 140 μm, 150 μm, 160 μm, etc. In one embodiment, the upper limit of the value range of the distance D1 is 90 μm, 100 μm, 110 μm, 120 μm, 130 μm, 140 μm, 150 μm, 160 μm, 170 μm, etc. The upper and lower limits of the value range of the distance D1 may be set as needed, where the upper limit may be greater than the lower limit.

In at least one embodiment of the disclosure, as shown in FIGS. 3A and 3B, the display module may further include at least one dam 350 located in the non-display area 11c, and an orthographic projection of the dam 350 on the substrate 100 is located between the display area and the orthographic projection of the first boundary T1 on the substrate 100.

The inorganic protective layer 20 (e.g., the first inorganic encapsulation layer 510 included therein) covers the dam 350, which is equivalent to the dam 350 changing an extension direction of the inorganic protective layer 20, and in the case of cracking of the inorganic protective layer 20, the dam 350 can change the direction of stress transmission caused by cracks to block the extension of the cracks. In addition, the dam 350 is in interlocking connection (direct or indirect connection) with the inorganic protective layer 20, thereby reducing the risk of the inorganic protective layer 20 falling off. In addition, the dam 350 may facilitate the preparation of an encapsulation structure (e.g., a third encapsulation layer described below) to block a fluid (ink) in a process such as inkjet printing.

In an embodiment of the disclosure, the number of dams 350 is not limited, may be set to one, or may be set to two as shown in FIG. 4, or may be provided to three or more, and specifically may be designed according to the requirements of the actual process, which is not limited herein.

For example, as shown in FIGS. 3A and 3B, the first boundary T1 of the polarizer 600 falls outside a region where the dam 350 is located. That is, the spacer layer 400 may be provided independently, and the orthographic projection of the dam 350 on the substrate 100 is located between the display area and the orthographic projection of the first boundary T1 on the substrate 100. In this way, it can be ensured that the inorganic protective layer 20 (e.g., including the first inorganic encapsulation layer) can cover the dam 350 to ensure the encapsulation effect of the display module.

For example, as shown in FIGS. 3A and 3B, the spacer layer 400 is located on a side of the dam 350 away from the display area, and a first gap P1 is provided between the spacer layer and the dam 350 adjacent to the spacer layer. The inorganic protective layer 20 (e.g., including the first inorganic encapsulation layer and/or a pixel defining layer) located in the first gap P1 is in contact with the first signal line 111. Alternatively, an inorganic layer that is in contact with the first signal line 111 is provided between the inorganic protective layer 20 located in the first gap P1 and the first signal line 111. For example, the inorganic layer may be the first inorganic encapsulation layer mentioned in the above embodiments and/or a pixel defining layer mentioned in the following embodiments. There is no spacer layer at the first gap, or the spacer layer is provided with an opening at the first gap, and a moisture intrusion path extending from the bend area to the display area can be blocked, thereby preventing moisture from extending to the display area through the spacer layer, and ensuring the inorganic encapsulation.

In one embodiment, the display module further includes a second inorganic layer between the substrate and the first signal line. In the first gap P1, the second inorganic layer is in contact with the inorganic protective layer, ensuring the inorganic encapsulation. The second inorganic layer may include one or more of a gate insulating layer, a capacitive dielectric layer, an interlayer insulating layer, and an inorganic buffer layer.

For example, as shown in FIGS. 3A and 3B, the orthographic projection of the first boundary T1 on the substrate 100 is located on a side of an orthographic projection of the first gap P1 on the substrate 100 away from the display area. With such an arrangement, the first boundary can avoid a weak area, i.e., the region where the first gap is located, thus avoiding the situation in which the first signal line is likely to be corroded by ions overflowing from the first boundary of the polarizer when the first boundary is opposite to the first gap, i.e., when the orthographic projection of the first boundary on the substrate overlaps with the orthographic projection of the first gap on the substrate.

For example, as shown in FIGS. 3A and 3B, at least two dams 350 are provided. The at least two dams 350 are arranged in a direction away from the display area, and a second gap P2 is provided between adjacent dams 350. The inorganic protective layer 20 located in the second gap P2 is in contact with the first signal line 111, or an inorganic layer that is in contact with the first signal line 111 is provided between the inorganic protective layer 20 located in the first gap P1 and the first signal line 111. For example, the inorganic layer may be the first inorganic encapsulation layer mentioned in the above embodiments and/or a pixel defining layer mentioned in the following embodiments. There is no spacer layer at the second gap, or the spacer layer is provided with an opening at the second gap, and a moisture intrusion path extending from the bend area to the display area can be blocked, thereby preventing moisture from extending to the display area through the spacer layer, and ensuring the inorganic encapsulation.

For example, as shown in FIGS. 3A and 3B, the orthographic projection of the first boundary T1 on the substrate 100 is located on a side of an orthographic projection of the second gap P2 on the substrate 100 away from the display area.

For example, as shown in FIGS. 3A and 3B, at least a portion of the at least one dam 350 and the spacer layer are disposed in the same layer.

For example, as shown in FIGS. 3A and 3B, the orthographic projection of the dam 350 on the substrate 100 overlaps with the orthographic projection of the inorganic protective layer 20 on the substrate 100.

For example, as shown in FIGS. 3A and 3B, the display module further includes a first inorganic encapsulation layer 510 and/or a pixel defining layer 330. In the non-display area, at least a portion of the first inorganic encapsulation layer 510 is used as at least a portion of the inorganic protective layer 20, and/or at least a portion of the pixel defining layer is used as at least a portion of the inorganic protective layer 20.

For example, as shown in FIGS. 3A and 3B, in the non-display area, an orthographic projection of a fifth boundary T5 of the pixel defining layer 330 on the substrate 100 is located on a side of the orthographic projection of the third boundary T3 on the substrate 100 away from the display area. Alternatively, the orthographic projection of the fifth boundary T5 on the substrate 100 is located on a side of the orthographic projection of the third boundary T3 on the substrate 100 close to the display area. Alternatively, the orthographic projection of the fifth boundary T5 on the substrate 100 overlaps and is collinear with, for example, coincides with the orthographic projection of the third boundary T3 on the substrate 100.

For example, as shown in FIGS. 3A and 3B, in the non-display area, an orthographic projection of a sixth boundary T6 of the first inorganic encapsulation layer 510 on the substrate 100 is located on the side of the orthographic projection of the third boundary T3 on the substrate 100 away from the display area. Alternatively, the orthographic projection of the sixth boundary T6 on the substrate 100 is located on the side of the orthographic projection of the third boundary T3 on the substrate 100 close to the display area. Alternatively, the orthographic projection of the sixth boundary T6 on the substrate 100 overlaps and is collinear with, for example, coincides with the orthographic projection of the third boundary T3 on the substrate 100.

For example, as shown in FIGS. 3A and 3B, in the non-display area, the orthographic projection of the fifth boundary T5 of the pixel defining layer 330 on the substrate 100 is located on a side of the orthographic projection of the sixth boundary T6 of the first inorganic encapsulation layer 510 on the substrate 100 close to the display area. Alternatively, the orthographic projection of the fifth boundary T5 on the substrate 100 is located on a side of the orthographic projection of the sixth boundary T6 on the substrate 100 away from the display area. Alternatively, the orthographic projection of the fifth boundary T5 on the substrate 100 overlaps and is collinear with, for example, coincides with the orthographic projection of the sixth boundary T6 on the substrate 100.

For example, as shown in FIGS. 3A and 3B, in the non-display area, the orthographic projection of the fifth boundary T5 of the pixel defining layer 330 on the substrate 100 is located on the side of the orthographic projection of the first boundary T1 on the substrate 100 close to the display area. Alternatively, the orthographic projection of the fifth boundary T5 on the substrate 100 is located on the side of the orthographic projection of the first boundary T1 on the substrate 100 away from the display area. Alternatively, the orthographic projection of the fifth boundary T5 on the substrate 100 overlaps and is collinear with, for example, coincides with the orthographic projection of the first boundary T1 on the substrate 100.

For example, as shown in FIGS. 3A and 3B, in the non-display area, a distance D2 between the orthographic projection of the fifth boundary T5 of the pixel defining layer 330 on the substrate 100 and the orthographic projection of the first boundary T1 on the substrate 100 is greater than or equal to 30 μm and less than or equal to 120 μm. In this way, the coverage area of the pixel defining layer on the spacer layer can be ensured to improve the ion blocking effect, and a space can also be reserved for the other film layers in the inorganic protective layer to wrap around the boundary of the pixel defining layer, to avoid that the edge of the inorganic protective layer extends too far to be detrimental to the extremely narrow border design of the display module. In one embodiment, the distance D2 is 75 μm. In one embodiment, the distance D2 may be 40 μm, 50 μm, 60 μm, 70 μm, 80 μm, 90 μm, 100 μm, 110 μm, etc. In one embodiment, the lower limit of the value range of the distance D2 is 30 μm, 40 μm, 50 μm, 60 μm, 70 μm, 80 μm, 90 μm, 100 μm, 110 μm, etc. In one embodiment, the upper limit of the value range of the distance D2 is 40 μm, 50 μm, 60 μm, 70 μm, 80 μm, 90 μm, 100 μm, 110 μm, 120 μm, etc. The upper and lower limits of the value range of the distance D2 may be set as needed, where the upper limit may be greater than the lower limit. In one embodiment, the orthographic projection of the fifth boundary T5 of the pixel defining layer 330 on the substrate 100 is located on the side of the orthographic projection of the third boundary T3 on the substrate 100 away from the display area. In one embodiment, the orthographic projection of the fifth boundary T5 of the pixel defining layer 330 on the substrate 100 is located on the side of the orthographic projection of the first boundary T1 on the substrate 100 close to the display area.

In some embodiments of the disclosure, in the non-display area, the orthographic projection of the sixth boundary T6 of the first inorganic encapsulation layer 510 on the substrate 100 is located on the side of the orthographic projection of the first boundary T1 on the substrate 100 close to the display area. Reference can be made to the relevant description of the embodiments shown in FIGS. 6A to 6E for details. Alternatively, in some other embodiments of the disclosure, the orthographic projection of the sixth boundary T6 on the substrate 100 is located on the side of the orthographic projection of the first boundary T1 on the substrate 100 away from the display area, as shown in FIGS. 3A and 3B specifically. Alternatively, in some other embodiments of the disclosure, the structure shown in FIGS. 3A and 3B may be modified such that the orthographic projection of the sixth boundary T6 on the substrate 100 is collinear with, for example, coincides with the orthographic projection of the first boundary T1 on the substrate 100.

For example, as shown in FIG. 6C or FIG. 6D, in the non-display area, a distance D3 between the orthographic projection of the sixth boundary T6 of the first inorganic encapsulation layer 510 on the substrate 100 and the orthographic projection of the first boundary T1 on the substrate 100 is greater than or equal to 5 μm and less than or equal to 95 μm. In this way, the coverage area of the first inorganic encapsulation layer on the spacer layer can be ensured to improve the ion blocking effect, and a space can also be reserved for the other film layers in the inorganic protective layer to wrap around the boundary of the first inorganic encapsulation layer, to avoid that the edge of the inorganic protective layer extends too far to be detrimental to the extremely narrow border design of the display module. In one embodiment, the distance D3 is 50 μm. In one embodiment, the distance D3 is 10 μm, 20 μm, 30 μm, 40 μm, 50 μm, 60 μm, 70 μm, 80 μm, 90 μm, etc. In one embodiment, the lower limit of the value range of the distance D3 is 5 μm, 10 μm, 20 μm, 30 μm, 40 μm, 50 μm, 60 μm, 70 μm, 80 μm, 90 μm, etc. In one embodiment, the upper limit of the value range of the distance D3 is 10 μm, 20 μm, 30 μm, 40 μm, 50 μm, 60 μm, 70 μm, 80 μm, 90 μm, 95 μm, etc. The upper and lower limits of the value range of the distance D3 may be set as needed, where the upper limit may be greater than the lower limit. In one embodiment, the orthographic projection of the sixth boundary T6 of the first inorganic encapsulation layer 510 on the substrate 100 is located on the side of the orthographic projection of the third boundary T3 on the substrate 100 away from the display area. In one embodiment, the orthographic projection of the sixth boundary T6 of the first inorganic encapsulation layer 510 on the substrate 100 is located on the side of the orthographic projection of the first boundary T1 on the substrate 100 close to the display area.

In one embodiment, in the non-display area, one or both of the fifth boundary T5 and the sixth boundary T6 may be used as the second boundary T2. In one embodiment, in the non-display area, the fifth boundary T5 of the pixel defining layer 330 may be used as the second boundary T2. In one embodiment, in the non-display area, the sixth boundary T6 of the first inorganic encapsulation layer 510 may be used as the second boundary T2.

In at least one embodiment of the disclosure, as shown in FIG. 3C, the first signal line 111 may include a first conductive layer 111a, a second conductive layer 111b, and a third conductive layer 111c which are sequentially stacked in a thickness direction Z of the substrate, to increase the electrical conductivity of the first signal line 111, thereby reducing the resistance of the first signal line 111 (resulting in a voltage drop). For example, the first conductive layer 111a, the second conductive layer 111b, and the third conductive layer 111c may be sequentially made of titanium, aluminum and titanium, or molybdenum, aluminum and molybdenum, for example. Taking the structure of titanium, aluminum and titanium as an example, the first conductive layer 111a, the second conductive layer 111b and the third conductive layer 111c may be referred to as a first titanium metal layer, an aluminum metal layer and a second titanium metal layer, respectively.

For example, there is a notch (e.g., I-shaped or T-shaped) in a sidewall of a portion of the first signal line 111 that is located in the first gap; and a sidewall of the portion of the first signal line 111 that is covered by the spacer layer has a higher flatness than the sidewall of the portion of the first signal line 111 that is located in the first gap. Due to the protection of the spacer layer, the sidewall of the portion of the first signal line 111 that is covered by the spacer layer will not be corroded by an etching solution in a subsequent etching process (e.g., an anode patterning process), and accordingly the sidewall of the portion of the first signal line 111 that is covered by the spacer layer will not be corroded. The portion of the first signal line 111 located in the first gap is not protected by the spacer layer, the sidewall of the portion of the first signal line 111 that is located in the first gap is corroded, and the presence of the notch results in that the inorganic protective layer 20 on the sidewall of the portion of the first signal line 111 that is located in the first gap is thin and the inorganic protective layer 20 on the portion of the first signal line 111 that is covered by the spacer layer is thick, and the inorganic protective layer on the sidewall of the portion of the first signal line 111 that is located in the first gap is likely to be damaged by the ions overflowing from the first boundary of the polarizer, while the inorganic protective layer above the portion of the first signal line 111 that is covered by the spacer layer is less likely to be damaged by the ions overflowing from the first boundary of the polarizer, that is, the region where the first gap is located is a weak area.

For example, the minimum thickness d2 of the inorganic protective layer 20 between the portion of the first signal line 111 that is covered by the spacer layer and the first boundary is greater than the minimum thickness d1 of the inorganic protective layer 20 corresponding to the sidewall of the portion of the first signal line 111 that is located in the first gap. The inorganic protective layer 20 at the position where the orthographic projection of the first signal lines 111 on the substrate, the orthographic projection of the spacer layer on the substrate, the orthographic projection of the inorganic protective layer on the substrate, and the orthographic projection of the first boundary on the substrate overlap with one another has a thickness uniformity higher than that of the inorganic protective layer 20 corresponding to the sidewall of the portion of the first signal line 111 that is located in the first gap.

For example, there is a notch (e.g., I-shaped or T-shaped) in a sidewall of a portion of the first signal line 111 that is located in the second gap; and a sidewall of the portion of the first signal line 111 that is covered by the spacer layer has a higher flatness than the sidewall of the portion of the first signal line 111 that is located in the second gap.

For example, the minimum thickness of the inorganic protective layer 20 between the portion of the first signal line 111 that is covered by the spacer layer and the first boundary is greater than the minimum thickness of the inorganic protective layer 20 corresponding to the sidewall of the portion of the first signal line 111 that is located in the second gap.

The structure of a region (e.g. in the first gap) of the first signal line 111 that is not covered by the spacer layer may refer to FIG. 3C. However, in the actual process, the second conductive layer 111b has a better electrical conductivity and a large thickness to ensure that the first signal line 111 has a higher electrical conductivity. On this basis, the first conductive layer 111a and the third conductive layer 111c with greater strength (e.g., oxidation resistance, high structural strength, and good corrosion resistance) are provided to protect the second conductive layer 111b. Thus, the etching resistance of the second conductive layer 111b is less than the etching resistance of the first conductive layer 111a and the third conductive layer 111c. In this way, in an etching process (e.g., an anode etching process), the degree of etching of the second conductive layer 111b will be greater than the degrees of etching of the first conductive layer 111a and the third conductive layer 111c, causing a notch in the sidewall of the portion of the first signal line 111 that is located in the first gap. Thus, in a region (e.g., in the first gap and/or the second gap) where the inorganic protective layer 20 (e.g., the pixel defining layer 330 included therein) is in direct contact with the first signal line 111, the notch will affect the film-forming quality of the inorganic protective layer 20, leading to uneven thickness, where the thickness in a local region, for example, at the notch in the sidewall of the first signal line 111, is small, resulting in reduction of the blocking effect of the inorganic protective layer 20 on potassium ions.

The structure of the region where the first signal line 111 is covered by the spacer layer may refer to FIG. 3D, which is equivalent to a cross-section of the position in which the orthographic projection of the first signal line 111 on the substrate, the orthographic projection of the spacer layer on the substrate, the orthographic projection of the inorganic protective layer on the substrate, and the orthographic projection of the first boundary on the substrate overlap with one another. The spacer layer covers the first signal line 111 such that the first signal line 111 is shielded with no notch or a small notch is formed. In this way, in the region where the spacer layer is located, the film-forming quality of the inorganic protective layer 20 (e.g., the pixel defining layer 330 included therein) will not be affected, or will be less affected, and the inorganic protective layer has a higher film-forming quality and a uniform and large thickness to improve the effect of blocking potassium ions. In addition, the spacer layer with a larger thickness can protect the first signal line 111, enabling the inorganic protective layer 20 to have a higher film-forming quality when the inorganic protective layer 20 is formed on the spacer layer, thereby ensuring the blocking effect of the inorganic protective layer 20 on potassium ions.

It should be noted that in the etching process of a first electrode (e.g., an anode), there is no spacer layer in the first gap, and the first signal line 111 in the first gap is side-etched, and the spacer layer has been formed on the first signal line 111 before the etching process to prevent the first signal line from being side-etched, and the degree of side-etching of the portion of the first signal line 111 that is not covered by the spacer layer (e.g., located in the first gap) is greater than the degree of side-etching of the portion that is covered by the spacer layer. Accordingly, the sidewall of the portion of the first signal line 111 covered by the spacer layer has a relatively high flatness.

For example, as shown in FIGS. 3A and 3B, where the inorganic protective layer 20 includes the first inorganic encapsulation layer 510 and the pixel defining layer 330, in the non-display area, the first inorganic encapsulation layer 510 and the pixel defining layer 330 are in contact with each other to jointly block the intrusion of potassium ions.

In some other embodiments of the disclosure, as shown in FIG. 4, one of the at least one dam 350 may be used as the spacer layer 400. In this way, the dam 350 is used directly as the spacer layer 400 without the need for an additional preparation process of the display module, thereby facilitating the control of the preparation cost of the display module; and the size of the non-display area 11c will not be increased additionally, thereby facilitating the control of the design size of the display module. For example, an overlap region between the orthographic projection of the first signal line on the substrate and an orthographic projection of the dam on the substrate overlaps with the orthographic projection of the first boundary on the substrate.

For example, the dam 350 furthest from the display area 11a is used as the spacer layer 400 to ensure the encapsulation effect while ensuring the coverage of the polarizer 600. For example, an overlap region between the orthographic projection of the first signal line 111 on the substrate 100 and an orthographic projection of the dam 350 that is furthest from the display area on the substrate 100 overlaps with the orthographic projection of the first boundary T1 on the substrate 100.

For example, in at least one embodiment of the disclosure, as shown in FIG. 4, orthographic projections of all of the dams 350 on the substrate 100 are located within the orthographic projection of the inorganic protective layer 20 (e.g., including the first inorganic encapsulation layer 510) on the substrate 100 to ensure the encapsulation effect of the inorganic protective layer 20 (e.g., including the first inorganic encapsulation layer 510).

For example, with respect to the dam of which the orthographic projection on the substrate overlaps with the orthographic projection of the first boundary on the substrate, the width W of the dam is greater than or equal to 0.09 mm in a direction from the display area to the non-display area.

For example, with respect to the dam of which the orthographic projection on the substrate overlaps with the orthographic projection of the first boundary on the substrate, the width W of the dam is greater than or equal to the sum of an attachment tolerance and an alignment tolerance of the polarizer in the direction from the display area to the non-display area.

In some embodiments of the disclosure, as shown in FIG. 4, the width W of the spacer layer 400 (the dam 350 serving as the spacer layer 400) in a direction from the display area 11a to the non-display area 11c (in the direction indicated by the X-axis in FIG. 4) is greater than or equal to the sum of the attachment tolerance and the alignment tolerance of the polarizer 600. In consideration of the width of the spacer layer 400 (the dam 350 serving as the spacer layer 400), the attachment tolerance and the alignment tolerance are taken into account, and in the actual process, even if the position of the polarizer 600 is shifted, the edge of the polarizer and the first signal line 111 can be spaced apart by the spacer layer 400, thus ensuring the yield of the display module in the actual production process.

In at least one embodiment of the disclosure, the dam 350 may be prepared separately or, as shown in FIG. 4, at least a portion of the dam 350 may be prepared synchronously during the preparation of the drive circuit layer. For example, the drive circuit layer may include an inorganic buffer layer, a capacitive dielectric layer, an interlayer insulating layer, a gate insulating layer, and a flat layer. The dam 350 is in the same layer and made of the same material as one or more of the inorganic buffer layer, the capacitive dielectric layer, the interlayer insulating layer, the gate insulating layer, and the flat layer, that is, the dam 350 is formed synchronously during the preparation of the inorganic buffer layer, the capacitive dielectric layer, the interlayer insulating layer, the gate insulating layer, and the flat layer.

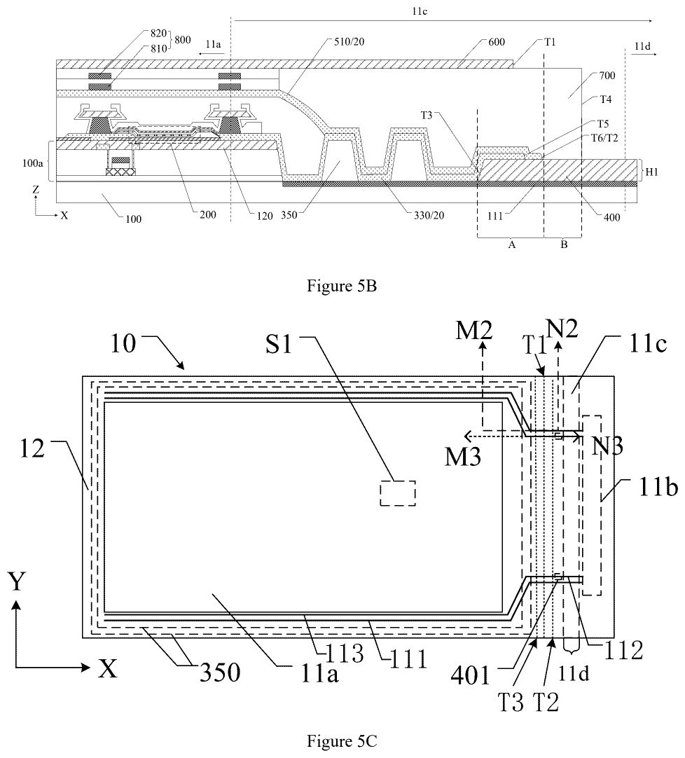

In at least one embodiment of the disclosure, as shown in FIGS. 5A to 5D, the conductive layer 111 of the display module may further include a second signal line 112. The second signal line 112 is located in the non-display area 11c and between the spacer layer 400 and the substrate 100. For example, the first signal line 111 and the second signal line 112 are arranged side-by-side in the same layer.

For example, the spacer layer 400 is provided with a via hole 401 in the non-display area, an orthographic projection of the via hole 401 on the substrate 100 overlaps with an orthographic projection of a portion of the second signal line 112 on the substrate 100, and the orthographic projection of the first boundary T1 on the substrate 100 is located between the display area and the orthographic projection of the via hole 401 on the substrate. For example, the orthographic projection of an edge (the second boundary T2) of the inorganic protective layer 20 (e.g., the first inorganic encapsulation layer 510 included therein) on the substrate 100 is located between the display area 11a and the orthographic projection of the via hole 401 on the substrate 100. In this way, while ensuring not to affect the via function of the via hole 401 (e.g., the via hole will not be covered by the filling layer 700 mentioned above), there may be a certain lateral distance between the edge of the polarizer 600 and the via hole 401 to further reduce the probability of ions that overflow from the edge of the polarizer 600 entering the via hole 401. The “lateral distance” is a distance along the X-axis.

For example, as shown in FIGS. 5A to 5D, a distance between the orthographic projection of the first boundary T1 on the substrate 100 and the orthographic projection of the via hole 401 on the substrate 100 in a direction perpendicular to the first boundary T1 or away from the display area is greater than or equal to 0.09 mm. In one embodiment, the distance between the orthographic projection of the first boundary T1 on the substrate 100 and the orthographic projection of the via hole 401 on the substrate 100 is greater than or equal to the sum of an attachment tolerance and an alignment tolerance of the polarizer 600. In this way, the first boundary can be prevented from being opposite the via hole due to the attachment error and the alignment error, and the risk that ions overflowing from the polarizer 600 intrude into the via hole 401 to corrode the second signal line 112 can be reduced.

For example, as shown in FIGS. 5A to 5D, the second signal line 112 and the first signal line 111 are disposed in the same layer and made of the same material.

For example, as shown in FIGS. 5A to 5D, the first signal line 111 is a power line, and/or the second signal line 112 is a touch trace.

For example, as shown in FIGS. 1 and 5A to 5D, the display panel further includes a bend area 11d, and the via hole 401 is located between the display area 11a and the bend area 11d.

In at least one embodiment of the disclosure, referring back to FIGS. 3A, 3B and 5D, a distance B between the orthographic projection of the edge (the second boundary T2) of the inorganic protective layer 20 (e.g., the first inorganic encapsulation layer 510 included therein) on the substrate 100 and the orthographic projection of the via hole 401 on the substrate 100 is greater than or equal to 0.09 mm. For example, the distance B is greater than or equal to the sum of the attachment tolerance and the alignment tolerance of the polarizer 600. In this way, the risk that ions overflowing from the polarizer 600 intrude into the via hole 401 to corrode the second signal line 112 can be reduced.

In one embodiment, the display module further includes a third signal line 113. The third signal line 113 is electrically connected to the second signal line 112 through the via hole 401, and the third signal line 113 is located between the inorganic protective layer 20 and the polarizer.

In at least one embodiment of the disclosure, as shown in FIGS. 6A to 6D, the display module may further include a touch functional layer 800. The touch functional layer 800 includes a touch electrode. The touch electrode is connected to the third signal line 113. The touch electrode is located in the display area 11a.

For example, the touch functional layer 800 is located between the first inorganic encapsulation layer 510 and the polarizer 600. The third signal line 113 extends along the inorganic protective layer 20 (e.g., including the first inorganic encapsulation layer 510) into the via hole 401 to be electrically connected to the second signal line 112, and the third signal line 113 is located between the inorganic protective layer 20 and the polarizer 600.

For example, the touch functional layer 800 includes a first electrode layer 810 and a second electrode layer 820. The first electrode layer 810 and the second electrode layer 820 form a touch unit for enabling a touch function. For example, one of the first electrode layer 810 and the second electrode layer 820 includes a plurality of first electrode strips in parallel and a plurality of second electrode strips in parallel, the first electrode strips and the second electrode strips intersecting to form touch units at the intersections; and the other of the first electrode layer 810 and the second electrode layer 820 includes a plurality of conductive bridges. The first electrode strips are cut off at positions where the first electrode strips intersect the second electrode strips, i.e., the first electrode strips are cut into a plurality of electrode blocks, and adjacent electrode blocks are electrically connected to each other via a respective conductive bridge.

For example, the third signal line 113 and at least a portion of the touch electrode are disposed in the same layer and made of the same material. It should be noted that the third signal line 113 may be of a single-layer design or may be of a double-layer design. For example, in the case of the single-layer design, the third signal line 113 and one of the first electrode layer 810 and the second electrode layer 820 may be disposed in the same layer and made of the same material. In the case of the double-layer design, one layer of the third signal line 113 may be disposed in the same layer and made of the same material as the first electrode layer 810, and the other layer thereof may be disposed in the same layer and made of the same material as the second electrode layer 820. In this way, the third signal line 113 may be formed by double layers of conductor wires in parallel to reduce the voltage drop generated thereon.

In at least one embodiment of the disclosure, as shown in FIGS. 6A to 6D, the display module may further include a touch buffer layer 540. In the non-display area, at least a portion of the touch buffer layer is used as at least a portion of the inorganic protective layer 20. Alternatively, the inorganic protective layer 20 may further include a touch buffer layer 540, the touch buffer layer 540 being located between the first inorganic encapsulation layer 510 and the touch functional layer 800. For example, the touch buffer layer 540 may cover the display area and extend to the non-display area. The touch buffer layer 540 is used for protecting a surface of the display module (e.g., a surface of the first inorganic encapsulation layer 510 facing away from the substrate 100) before the preparation of the touch functional layer 800, thereby reducing the risk of damaging the encapsulation of the display module due to the preparation process of the touch functional layer 800.

In one embodiment, an orthographic projection of a seventh boundary T7 of the touch buffer layer 540 on the substrate 100 is located on the side of the orthographic projection of the third boundary T3 on the substrate 100 away from the display area. In one embodiment, the orthographic projection of the seventh boundary T7 of the touch buffer layer 540 on the substrate 100 is located on the side of the orthographic projection of the third boundary T3 on the substrate 100 close to the display area. In one embodiment, the orthographic projection of the seventh boundary T7 of the touch buffer layer 540 on the substrate 100 overlaps and is collinear with, for example, coincides with the orthographic projection of the third boundary T3 on the substrate 100.

In one embodiment, the orthographic projection of the seventh boundary T7 of the touch buffer layer 540 on the substrate 100 is located on the side of the orthographic projection of the first boundary T1 on the substrate 100 away from the display area. In one embodiment, the orthographic projection of the seventh boundary T7 of the touch buffer layer 540 on the substrate 100 is located on the side of the orthographic projection of the first boundary T1 on the substrate 100 close to the display area. In one embodiment, the orthographic projection of the seventh boundary T7 of the touch buffer layer 540 on the substrate 100 overlaps and is collinear with, for example, coincides with the orthographic projection of the first boundary T1 on the substrate 100.

In at least one embodiment of the disclosure, as shown in FIGS. 6A to 6E, the orthographic projection of the sixth boundary T6 of the first inorganic encapsulation layer 510 on the substrate 100 is located on a side of the orthographic projection of a boundary (e.g., the seventh boundary T7) of the touch buffer layer 540 on the substrate 100 close to the display area, and at least a portion of the boundary (e.g., the seventh boundary T7) of the touch buffer layer 540 in the non-display area is the second boundary T2.

In at least one embodiment of the disclosure, as shown in FIGS. 6A to 6E, the orthographic projection of the first boundary T1 on the substrate 100 is located between the orthographic projection of the sixth boundary T6 of the first inorganic encapsulation layer 510 on the substrate 100 and the orthographic projection of the seventh boundary T7 of the touch buffer layer 540 (or an eighth boundary T8 of the inorganic insulating layer) on the substrate 100. As an example, the distance D1 between the orthographic projection of the third boundary T3 on the substrate 100 and the orthographic projection of the first boundary T1 on the substrate 100 is greater than or equal to 80 μm and less than or equal to 170 μm, and further, for example, is 125 μm; the distance D2 between the orthographic projection of the fifth boundary T5 of the pixel defining layer 330 on the substrate 100 and the orthographic projection of the first boundary T1 on the substrate 100 is greater than or equal to 30 μm and less than or equal to 120 μm, and further, for example, is 75 μm; the distance D3 between the orthographic projection of the sixth boundary T6 of the first inorganic encapsulation layer 510 on the substrate 100 and the orthographic projection of the first boundary T1 on the substrate 100 is greater than or equal to 5 μm and less than or equal to 95 μm, and further, for example, is 50 μm; and the distance D3 between the orthographic projection of the second boundary T2 (which may be the seventh boundary T7 of the touch buffer layer 540 or the eighth boundary T8 of the inorganic insulating layer) on the substrate 100 and the orthographic projection of the first boundary T1 on the substrate 100 is greater than or equal to 130 μm and less than or equal to 220 μm, and further, for example, is 175 μm.

For example, the distance D5 between the orthographic projection of the first boundary T1 on the substrate 100 and the bend area 11d may be 160 to 250 μm, i.e., may be greater than or equal to 160 μm and less than or equal to 250 μm, and further, for example, may be 205 μm. In this way, a sufficient distance can be ensured between the bend area 11d and the inorganic protective layer 20 to avoid cracking of the inorganic protective layer 20 when the bend area 11d is bent.

For example, as shown in FIGS. 6D and 6E, the touch functional layer 800 may include at least two conductive layers (the first electrode layer 810 and the second electrode layer 820 described above) and the inorganic insulating layer 550 between the conductive layers. In the non-display area, at least a portion of the inorganic insulating layer 550 is used as at least a portion of the inorganic protective layer 20. That is, the inorganic protective layer 20 may include the inorganic insulating layer 550.

In one embodiment, the orthographic projection of the eighth boundary T8 of the inorganic insulating layer 550 on the substrate 100 is located on the side of the orthographic projection of the third boundary T3 on the substrate 100 away from the display area. In one embodiment, the orthographic projection of the eighth boundary T8 of the inorganic insulating layer 550 on the substrate 100 is located on the side of the orthographic projection of the third boundary T3 on the substrate 100 close to the display area. In one embodiment, the orthographic projection of the eighth boundary T8 of the inorganic insulating layer 550 on the substrate 100 overlaps and is collinear with, for example, coincides with the orthographic projection of the third boundary T3 on the substrate 100.

In one embodiment, the orthographic projection of the eighth boundary T8 of the inorganic insulating layer 550 on the substrate 100 is located on the side of the orthographic projection of the first boundary T1 on the substrate 100 away from the display area. In one embodiment, the orthographic projection of the eighth boundary T8 of the inorganic insulating layer 550 on the substrate 100 is located on the side of the orthographic projection of the first boundary T1 on the substrate 100 close to the display area. In one embodiment, the orthographic projection of the eighth boundary T8 of the inorganic insulating layer 550 on the substrate 100 overlaps and is collinear with, for example, coincides with the orthographic projection of the first boundary T1 on the substrate 100.

In one embodiment, in the non-display area, the inorganic insulating layer 550 is in contact with the touch buffer layer 540. The thickness of the inorganic insulating layer 550 may be less than the thickness of the first inorganic encapsulation layer. The thickness of the touch buffer layer 540 may be less than the thickness of the first inorganic encapsulation layer.

For example, where the inorganic protective layer 20 includes the inorganic insulating layer 550, at least a portion of a boundary (e.g., the eighth boundary T8) of the inorganic insulating layer 550 located in the non-display area is the second boundary T2.

For example, in at least one embodiment of the disclosure, as shown in FIGS. 6D and 6E, the inorganic protective layer 20 may include one or more of the pixel defining layer 330, the first inorganic encapsulation layer 510, the touch buffer layer 540, and the inorganic insulating layer 550. In one embodiment, one or more of the fifth boundary T5 of the pixel defining layer 330, the sixth boundary T6 of the first inorganic encapsulation layer 510, the seventh boundary T7 of the touch buffer layer 540, and the eighth boundary T8 of the inorganic insulating layer 550 is used as the second boundary T2.

In one embodiment, the seventh boundary T7 may be located on a side of the eighth boundary T8 close to the display area. In one embodiment, the seventh boundary T7 may be located on a side of the eighth boundary T8 away from the display area. In one embodiment, the seventh boundary T7 may overlap and be collinear with, for example, coincide with the eighth boundary T8.

In one embodiment, the fifth boundary T5 may be located on a side of the sixth boundary T6 close to the display area. In one embodiment, the fifth boundary T5 may be located on a side of the sixth boundary T6 away from the display area. In one embodiment, the fifth boundary T5 may overlap and be collinear with, for example, coincide with the sixth boundary T6.

In one embodiment, in the non-display area, the touch buffer layer 540 may be in contact with the first inorganic encapsulation layer 510.

In one embodiment, the fifth boundary T5 of the pixel defining layer 330 and the sixth boundary T6 of the first inorganic encapsulation layer 510 may be located on the side, close to the display area, of the seventh boundary T7 of the touch buffer layer 540 and/or the eighth boundary T8 of the inorganic insulating layer 550. In one embodiment, the fifth boundary T5 of the pixel defining layer 330 and the sixth boundary T6 of the first inorganic encapsulation layer 510 may be located on the side, away from the display area, of the seventh boundary T7 of the touch buffer layer 540 and/or the eighth boundary T8 of the inorganic insulating layer 550.

In one embodiment, the display module further includes a first inorganic encapsulation layer and/or a pixel defining layer located between the touch functional layer and the substrate.

In at least one embodiment of the disclosure, as shown in FIGS. 5A and 5B, the display module may further include a light-emitting device layer and a flat layer 120. The light-emitting device layer is located in the display area 11a. For example, the light-emitting device layer is located between the first inorganic encapsulation layer 510 and the substrate 100. The light-emitting device layer includes a plurality of light-emitting devices 200, and the flat layer 120 is located between the light-emitting device layer and the substrate 100. The flat layer 120 is used to flatten a surface of the structure (the drive circuit layer) underneath it to facilitate the preparation of the light-emitting devices 200.

In at least one embodiment of the disclosure, as shown in FIGS. 5A and 5B, the spacer layer 400 and the flat layer 120 are disposed in the same layer and made of the same material. In this way, the arrangement of the spacer layer 400 does not need an additional preparation process of the display module, thereby facilitating the control of the preparation cost of the display module.

In at least one embodiment of the disclosure, as shown in FIGS. 5A and 5B, the flat layer 120 is an organic film layer for improving the flexibility of the display module.

In at least one embodiment of the disclosure, as shown in FIGS. 5A and 5B, the thickness H1 of the spacer layer 400 is greater than or equal to 1.8 μm and less than or equal to 2.4 μm. The spacer layer 400 may have a sufficient thickness within this value range to ensure the effect of spacing the inorganic protective layer 20 apart from the first signal line 111. The thickness H1 may be 1.9 μm, 2.0 μm, 2.1 μm, 2.2 μm, 2.3 μm, etc. The lower limit of the value range of the thickness H1 may be 1.8 μm, 1.9 μm, 2.0 μm, 2.1 μm, 2.2 μm, 2.3 μm, etc. The upper limit of the value range of the thickness H1 may be 1.9 μm, 2.0 μm, 2.1 μm, 2.2 μm, 2.3 μm, 2.4 μm, etc. The upper and lower limits of the value range of the thickness H1 may be set as needed, where the upper limit may be greater than the lower limit.

In some manufacturing scenarios of the display module, some functional film layers in the light-emitting devices are formed by means of evaporation, and some functional film layers of the light-emitting devices that emit light in different colors may be of the same type (e.g., hole injection layers and electron injection layers), and these film layers are prepared synchronously in a single process, which makes it difficult to independently design the functional film layers of the light-emitting devices that emit light in different colors, thus limiting the effectiveness of the microcavity effect. In addition, since there are various functional layers in each light-emitting device and some functional layers (e.g., light-emitting layers) in the light-emitting devices that emit light in different colors are made of different materials, it is necessary to perform multiple alignments during evaporation of these functional layers via masks (e.g., fine masks). In order to solve the problem of position offset caused by the alignment accuracy error, enough space (safety margin related to the alignment error) needs to be reserved between the different light-emitting devices to ensure that the location of the actual light-emitting region of each light-emitting device may have a certain overlap rate with the design location (design area). This actually compresses the design area of the light-emitting region of the light-emitting device, not only limiting the light-emitting area of the light-emitting device, but also preventing a further increase of the arrangement density of the light-emitting devices, and it is difficult to further improve the pixels-per-inch PPI of the display module.

In the disclosure, the functional film layers of adjacent light-emitting devices are separated by providing the isolation structure at the gap between the light-emitting devices, and in the evaporation process for the functional film layers, it is only necessary to carry out the whole-surface evaporation on the display module without the need to separately prepare the functional film layers of each light-emitting device by means of a fine mask. In this process, there is no need to take into account the problem of alignment accuracy during evaporation, and thus the gap between the light-emitting devices can be designed to have a small size to increase the PPI (the principle of which can refer to the relevant description of the following embodiments related to FIGS. 8 to 12).

During the process of preparing the display module based on the isolation structure, since the evaporation is carried out without the fine mask or is carried out using an open mask, an evaporated film layer in the non-display area is removed in order to prevent an evaporation material from remaining in the non-display area and affecting the structural design of the non-display area. This will result in limitations on the number and thickness of film layers of the encapsulation structure (e.g., an encapsulation layer described below) of the non-display area, thereby reducing the blocking effect against ion intrusion. Therefore, in this case, it is particularly necessary to provide the spacer layer to reduce the intrusion of ions into the signal line in the conductive layer.

Several design structures of the display module including an isolation structure are illustrated by way of some specific embodiments.

In at least one embodiment of the disclosure, referring back to FIGS. 3A and 3B, the display module includes an isolation structure 300 located on the substrate 100. For example, the isolation structure 30 has a plurality of isolation openings 301, at least a portion of the light-emitting device 200 is located in a respective isolation opening 301, and the plurality of isolation openings 301 respectively define the light-emitting devices 200. In this way, the isolation openings 301 exhibit a grid-like structure.

For example, an orthographic projection, on the substrate 100, of the end of the isolation structure 300 facing away from the substrate 100 is located within an orthographic projection, on the substrate 100, of the end of the isolation structure 300 facing toward the substrate 100. In this way, the light-emitting devices 200 that emit light in different colors are prepared separately by means of the isolation structure 300, and the thicknesses of film layers in the light-emitting devices 200 are controlled accurately to improve the light-emitting efficiency of the light-emitting devices 200. In addition, the light-emitting devices 200 are prepared based on the isolation structure 300, at least some of the film layers in the light-emitting devices 200 may be prepared using an open mask or without a mask, and the positions of the light-emitting devices 200 are controlled accurately, and accordingly, the gap between the light-emitting devices 200 may be greatly reduced, thereby increasing the pixels-per-inch PPI of the display module.

In at least one embodiment of the disclosure, referring back to FIGS. 3A and 3B, the display module may further include a pixel defining layer 330 located on the substrate and provided with pixel openings. The pixel openings 302 are in communication with corresponding isolation openings 301. For example, the pixel defining layer 330 is located between substrate 100 and the isolation structure 300 and covers the display area 11a. A plurality of pixel openings 302 corresponding to the isolation openings 301 are defined from the pixel openings 302. An orthographic projection of the pixel opening 302 on the substrate 100 is located within an orthographic projection of the corresponding isolation opening 301 on the substrate 100. In one embodiment, the pixel defining layer 300 may be provided with a clearance opening, and the isolation structure 300 is located in the clearance opening.

In one embodiment, the pixel defining layer includes a pixel define portion located on a side of the first electrode away from the substrate and covering an edge of the first electrode, and the first electrode is exposed from the pixel opening.

In at least one embodiment of the disclosure, the pixel defining layer 330 may be an inorganic film layer. The inorganic layer has a high compactness and a high resistance capability such that the design thickness of the display module can be reduced. In addition, the pixel defining layer 330 having a small thickness facilitates an improvement in the continuity of an electrode (e.g., a second electrode described below) in the light-emitting device 200.

In at least one embodiment of the disclosure, the thickness of the pixel defining layer 330 is less than the thickness of the first inorganic encapsulation layer 510. The pixel defining layer 330 is designed to be as thin as possible while ensuring the insulation effect, and the pixel defining layer 330 is generally thinner than the first inorganic encapsulation layer 510 used for encapsulation.

For example, the pixel defining layer 330 may have a thickness of about 3000 Angstroms.

In at least one embodiment of the disclosure, referring back to FIGS. 3A and 3B, in the non-display area, at least a portion of the pixel defining layer 330 is used as at least a portion of the inorganic protective layer 20, i.e., the inorganic protective layer 20 includes the pixel defining layer 330. For example, in the non-display area 11c, the orthographic projection of the first boundary T1 of the polarizer 600 on the substrate 100 coincides with, or overlaps and is collinear with the orthographic projection of the fifth boundary T5 of the pixel defining layer 330 on the substrate 100. Alternatively, in the non-display area 11c, the orthographic projection of the first boundary T1 of the polarizer 600 on the substrate 100 is located on a side of the orthographic projection of the fifth boundary T5 of the pixel defining layer 330 on the substrate 100 away from the display area. In one embodiment, in the non-display area 11c, the orthographic projection of the first boundary T1 of the polarizer 600 on the substrate 100 is located on a side of the orthographic projection of the fifth boundary T5 of the pixel defining layer 330 on the substrate 100 close to the display area.

The edge of the polarizer 600 and the first signal line 111 are spaced apart by both the first inorganic encapsulation layer 510 and the pixel defining layer 330, thereby further improving the effect of intercepting ions to further reduce the risk that ions intrude into the first signal line 111 to corrode the first signal line 111.

In at least one embodiment of the disclosure, referring back to FIGS. 3A and 3B, the isolation structure 300 includes a support 310 and a crown 320 located on a side of the support 310 facing away from the substrate 100. An orthographic projection of the support 310 on the substrate 100 is located within an orthographic projection of the crown 320 on the substrate 100, that is, the isolation structure 300 is generally wide at the top and narrow at the bottom such that some of the film layers (e.g., light-emitting units described below) in the light-emitting device 200 are cut off at the edge of the isolation structure 300 during evaporation, thereby lowering the risk of crosstalk between adjacent light-emitting devices. The area of the orthographic projection of the support 310 on the substrate 100 may be smaller than the area of the orthographic projection of the crown 320 on the substrate 100.

In at least one embodiment of the disclosure, referring back to FIGS. 3A and 3B, the light-emitting device 200 includes a first electrode 210, at least one light-emitting unit 220, and a second electrode 230 which are sequentially stacked on the substrate 100. The light-emitting unit 220 and the second electrode 230 of each of the light-emitting devices 200 are located in a corresponding isolation opening 301. In one embodiment, the second electrode is electrically connected to the first signal line. In one embodiment, the support 310 is a conductive structure, and the second electrode 230 is connected to a sidewall of the support 310. During the preparation of the light-emitting unit 220, the isolation structure 300 (the crown 320) limits a diffusion range of the evaporation material such that an orthographic projection of an edge of the crown 320 on the substrate 100 is located within orthographic projections of the light-emitting unit 220 and the second electrode 230 on the substrate 100. Reference can be made to the following relevant description of the embodiment of a method for preparing the display module for details, which will not be repeated herein.

In at least one embodiment of the disclosure, each of the light-emitting devices 200 includes at least two light-emitting units 220 stacked in the thickness direction Z of the substrate. Where the light-emitting device 200 includes a plurality of light-emitting units 220 (i.e., a laminated light-emitting device), the light-emitting device 200 may have a higher light-emitting efficiency, but the second electrode 230 has a lower voltage (a higher negative voltage, e.g. approximately −5.4 V at a brightness of 600 nit, approximately −6.5 V at a brightness of 800 nit, and approximately −7.5 V at a brightness of 2000 nit). Where the first signal line 111 is connected to the second electrode 230, the first signal line 111 will also apply a lower voltage, which results in a more severe attraction effect on potassium ions. This problem can be improved significantly by using the embodiments of the present application.

Where the display module includes the pixel defining layer 330, the light-emitting unit 220 and the second electrode 230 of the light-emitting device 200 will fill the pixel opening 302 and extend to a surface of the pixel defining layer 330 facing away from the substrate 100. Thus, in the case of a thin pixel defining layer 330, the second electrode 230 has a good film-forming effect (high degree of continuity of the film layers) on a sidewall of the pixel opening 302.

For example, the light-emitting unit may include a first functional layer 221, a light-emitting layer 222 and a second functional layer 223 which are stacked in the thickness direction Z of the substrate. The first functional layer 221, the light-emitting layer 222 and the second functional layer 223 are sequentially stacked on the first electrode 210. The first functional layer 221 may include a hole injection layer, a hole transport layer, an electron blocking layer, etc. The second functional layer 223 may include an electron injection layer, an electron transport layer, a hole blocking layer, etc. It should be noted that due to the crosstalk of carriers (holes and electrons) mainly between the adjacent light-emitting devices 200 through the first functional layer 221, the isolation structure 300 needs to be arranged in such a way that the first functional layers 221 of the respective light-emitting devices 200 are electrically disconnected from each other.

In at least one embodiment of the disclosure, the first functional layer 221 and the second functional layer 223 may be involved in forming the microcavity structure of the light-emitting device 200; and the first functional layers 221 and the second functional layers 223 of the light-emitting devices 200 that emit light in different colors may be of the same type. Thus, in the absence of the isolation structure 300, the first functional layer 221 and the second functional layer 223 of each light-emitting device 200 may serve as a common layer and thus have the same thickness. Where the isolation structure 300 is adopted, the thicknesses of the first functional layer 221 and the second functional layer 223 of each of the light-emitting devices 200 that emit light in different colors may be designed independently (either equal or unequal) such that the thicknesses of the film layers constituting the microcavity structure are controlled accurately to improve the microcavity effect of the microcavity structure.

In at least one embodiment of the disclosure, referring back to FIGS. 3A and 3B, the pixel defining layer 330 covers an edge of first electrode 210. In this way, the pixel defining layer 330 enables the first electrode 210 to have a large design area, to expand the light-emitting area of the light-emitting device 200. For example, where the display module is provided with the pixel defining layer 330, the first electrode 210 of the light-emitting device 200 may be designed to have a large area to avoid a situation in which the actual light-emitting area of the light-emitting device is difficult to be guaranteed due to a position offset between the first electrode 210 and the isolation structure 300 in the actual process (an error due to process precision), thereby increasing the aperture ratio (related to the light-emitting area of the light-emitting device) and brightness of a display image of the display module. For example, in the absence of the pixel defining layer 330, in order to avoid the connection between the first electrode 210 and the isolation structure 300, the design area of the first electrode 210 is limited. In the case of a position offset of the first electrode 210, the actual light-emitting area of the light-emitting device may be smaller than the area of the design region (the region under ideal conditions), resulting in a decrease in the brightness of the light-emitting device.

For example, in at least one embodiment of the disclosure, the first electrode may be provided as an anode and the second electrode may be provided as a cathode.

Since the isolation structure 300 has a shape with a width top and a narrow bottom, the first functional layer 221 is cut off at the edge of the crown 320 during the evaporation, i.e., the first functional layer 221 will not be connected to a conductive portion (e.g., the support 310) of the isolation structure 300, to avoid the crosstalk between the adjacent light-emitting devices 200.

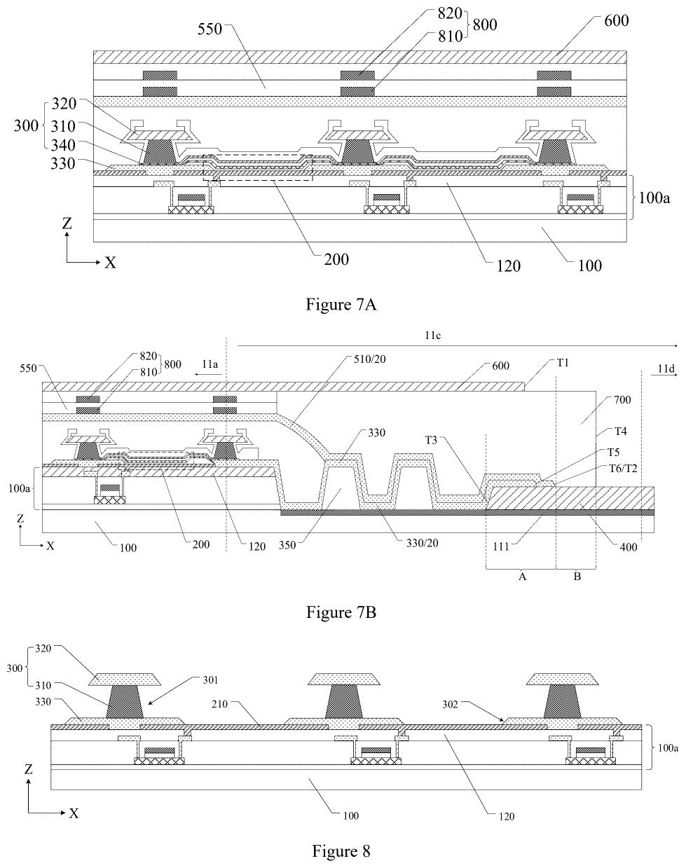

In at least one embodiment of the disclosure, as shown in FIGS. 7A and 7B, the isolation structure 300 may further include an auxiliary support 340. The auxiliary support 340 is located on a side of the support 310 facing away from the crown 320, and the orthographic projection of the support 310 on the substrate 100 is located within an orthographic projection of the auxiliary support 340 on the substrate 100. For example, the auxiliary support 340 is located between the support 310 and the pixel defining layer 330. For example, the orthographic projection of the auxiliary support 340 on the substrate 100 is located within the orthographic projection of the crown 320 on the substrate 100. The area of the orthographic projection of the support 310 on the substrate 100 may be smaller than the area of the orthographic projection of the auxiliary support 340 on the substrate 100.

For example, the auxiliary support 340 is a conductive structure. A portion of a surface of the auxiliary support 340 facing away from the substrate 100 that is not covered by the support 310 may be used to make contact with the second electrode 230. With respect to a sidewall of the support 310, the second electrode 230 has a greater deposition thickness on the surface of the auxiliary support 340, and the auxiliary support 340 has a great contact area and bonding strength with the second electrode 230, thereby reducing the impedance between the second electrode 230 and the isolation structure 300.

For example, the crown 320, the support 310, and the auxiliary support 340 may be sequentially made of titanium, aluminum, and molybdenum, the corrosion resistances of titanium, molybdenum and aluminum are reduced sequentially, and thus the isolation structure 300 as shown in FIGS. 7A and 7B can be formed.

For example, in some embodiments of the disclosure, referring back to FIGS. 3A and 3B, the support 310 and the crown 320 are two separate film layers, the support 310 is a conductive structure, and the second electrode 230 of the light-emitting device 200 is connected to the support. For example, further, in the direction Z perpendicular to the substrate 100, the support 310 has a cross-section shape of a right trapezoid, and the crown is located at a top edge of the support 310. In this case, deposition of the evaporation material of the second electrode 230 on the sidewall of the support 310 can be facilitated, to increase the overlap yield of the second electrode 230 and the support 310.

For example, in some other embodiments of the disclosure, the isolation structure 300 shown in FIGS. 3A and 3B may be modified such that the support 310 and the crown 320 are of an integrated structure. The isolation structure 300 is a conductive structure, and the second electrode 230 of the light-emitting device 200 is connected to the support 310. The integrated structure may be a separate film layer in which there is no physical interface. The support 310 and the crown 320 are two parts of the integrated structure. For example, further, in a direction perpendicular to the substrate 100, the crown 320 has a cross-section shape of an inverted trapezoid, with an upper base of the inverted trapezoid facing toward the substrate 100, i.e. the upper base of the inverted trapezoid being located between the substrate 100 and a lower base of the inverted trapezoid.

In at least one embodiment of the disclosure, referring back to FIGS. 3A and 3B, the display module may further include a second inorganic encapsulation layer 520 located on a side of the light-emitting device away from the substrate. The second inorganic encapsulation layer includes a plurality of encapsulation units which are spaced apart from each other and which correspond to the isolation openings. The encapsulation units cover the light-emitting devices confined by the corresponding isolation openings. For example, the second inorganic encapsulation layer 520 is located between the isolation structure 300 and the first inorganic encapsulation layer 510, and the second inorganic encapsulation layer 520 covers the isolation opening 301, and the orthographic projection of the isolation opening 301 on the substrate 100 is within an orthographic projection of the second inorganic encapsulation layer 520 on the substrate 100.

In one embodiment, in the non-display area, the orthographic projection of the spacer layer on the substrate does not overlap with the orthographic projection of the second inorganic encapsulation layer on the substrate, that is, the orthographic projection of the spacer layer 400 on the substrate 100 is located outside the orthographic projection of the second inorganic encapsulation layer 520 on the substrate 100. The factor that the second inorganic encapsulation layer 520 does not cover the spacer layer 400 is related to the process of preparing the light-emitting device 200 based on the isolation structure 300. Reference can be made to the relevant description of the embodiments shown in FIGS. 8 to 12.

In one embodiment, the display module further includes a first inorganic encapsulation layer located on a side of the second inorganic encapsulation layer away from the substrate, and in the non-display area, at least a portion of the first inorganic encapsulation layer is used as at least a portion of the inorganic protective layer 20. In one embodiment, the thickness of the pixel defining layer is less than the thickness of the first inorganic encapsulation layer.

In at least one embodiment of the disclosure, referring back to FIGS. 3A and 3B, the display module further includes a third encapsulation layer 530 located between the first inorganic encapsulation layer 510 and the second inorganic encapsulation layer 520.

For example, the third encapsulation layer 530 located between the first inorganic encapsulation layer 510 and the second inorganic encapsulation layer 520 forms an encapsulation structure 500.

For example, the second inorganic encapsulation layer 520 is an inorganic layer and the third encapsulation layer 530 is an organic layer. The inorganic layer has a high compactness for isolating water and oxygen, and the third encapsulation layer 530, which is an organic layer, has a great thickness to flatten the surface of the display module.

In one embodiment, the display module further includes at least one dam located in the non-display area, and the third encapsulation layer is located on a side of the at least one dam close to the display area. The dam may be used for blocking the overflow of an organic material during the preparation of the third encapsulation layer.

In at least one embodiment of the disclosure, the thickness of the pixel defining layer 330 is less than the thickness of the second inorganic encapsulation layer 520. The pixel defining layer 330 has a thickness of about 3000 Angstroms, and the second inorganic encapsulation layer 520 has a thickness of about 10500 Angstroms.

It should be noted that even in the absence of the isolation structure 300, the display module may include the encapsulation structure 500, in which case, the second inorganic encapsulation layer 520 may extend to the edge of the polarizer 600. Where the isolation structure 300 is adopted, due to the process reasons described above, the second inorganic encapsulation layer 520 no longer extends to the edge of the polarizer 600, but the pixel defining layer 330, which is used as an inorganic layer, extends to the edge of the polarizer 600, that is, the pixel defining layer 330, which is thin, replaces the second inorganic encapsulation layer 520, which is thick, at the edge of the polarizer 600, thus reducing the ion blocking effect of the film layer at this position and making it more necessary to provide the spacer layer 400.

In at least one embodiment of the disclosure, the second inorganic encapsulation layer 520 includes a plurality of encapsulation units 521 corresponding to the isolation openings 301 (e.g., on a one-to-one basis), and the encapsulation units 521 cover the corresponding isolation openings 301. The reason why the second inorganic encapsulation layer 520 is composed of a plurality of encapsulation units 521 is related to a specific process of preparing the light-emitting device 200 based on the isolation structure 300. Reference can be made to the relevant description of the embodiments shown in FIGS. 8 to 12.

In at least one embodiment of the disclosure, the plurality of light-emitting devices 200 are classified as light-emitting devices that emit light in various colors respectively, and the encapsulation units 521 corresponding to the light-emitting devices 200 that are adjacent to each other and emit light in different colors respectively are spaced apart from each other. The light-emitting devices 200 are prepared in batches. During the preparation of each batch, the encapsulation units 521 can protect the prepared light-emitting devices 200. Correspondingly, in these preparation processes, the second inorganic encapsulation layer 520 is formed into a plurality of encapsulation units 521 spaced apart from each other, and the encapsulation units 521 correspond to the isolation openings 301, respectively, to cover the light-emitting devices 200 confined in the isolation openings 301 for protection.

In at least one embodiment of the disclosure, referring back to FIGS. 3A and 3B, the encapsulation unit 521 extends to a side of the isolation structure 300 (the crown 320 included therein) facing away from the substrate 100; and between the light-emitting devices 200 that are adjacent to each other and emit light in different colors, the portion of each encapsulation unit 521 that is located at the isolation structure 300 and faces away from the substrate 100 is spaced apart from the isolation structure 300 to form an overhanging portion. It should be noted that in the process of preparing the third encapsulation layer 530 after all the light-emitting devices 200 are prepared, the third encapsulation layer 530 fills a gap between the overhanging portion and the isolation structure 300 (the crown 320 included therein).

For example, the light-emitting devices 200 are classified as light-emitting devices that emit red light (R), green light (G), and blue light (B), respectively. In the preparation process, the light-emitting devices R, G, and B are prepared sequentially. During the preparation of the light-emitting devices R, a light-emitting device R is formed in each of the isolation openings 301, the second inorganic encapsulation layer 520 is prepared on the display module to cover the light-emitting devices R, and then the second inorganic encapsulation layer 520, the second electrodes and the light-emitting units are removed from some of the isolation openings 301 (which are used for forming the light-emitting devices G, B in the final product). In this process, the second inorganic encapsulation layer 520 is used for protecting the light-emitting devices R in the other isolation openings 301. Based on this approach, the light-emitting devices G, B are then sequentially prepared and the second inorganic encapsulation layer 520 is formed ultimately. That is, the second inorganic encapsulation layer 520 on the entire display module is prepared by multiple processes, and the second inorganic encapsulation layer 520 is also formed into a plurality of encapsulation units 521 spaced apart from each other.

The structures of some elements in the display module have been briefly described above, and a method for preparing a display module is exemplarily described below by taking the display module shown in FIGS. 5A and 5B as an example.

As shown in FIGS. 8 and 5B, a substrate 100 is provided and an array of first electrodes 210 are formed on the substrate 100, the first electrodes 210 being formed in a display area. A dam 350 and a spacer layer 400 are formed in a non-display area 11c. An insulating material film layer (e.g., an inorganic material film layer) is deposited on the substrate 100 on which the first electrode 210 is formed. A support 310 and a crown 320 are formed on the display module to obtain an isolation structure 300 having isolation openings enclosed. The insulating material film layer is subjected to a patterning process to form a pixel defining layer 330 (which is grid-shaped in the plane of the display area). The pixel defining layer 330 covers a gap between the adjacent first electrodes 210, extends to the non-display area 11c, completely covers the dam 350, and covers a portion of a surface of the spacer layer 400 facing away from the substrate 100.

In an embodiment of the disclosure, the patterning process may be a photolithographic patterning process, which, for example, may include: coating a photoresist on a structural layer to be patterned, exposing the photoresist using a mask, developing the exposed photoresist to obtain a photoresist pattern, etching (optionally wet or dry etching) the structural layer using the photoresist pattern, and then optionally removing the photoresist pattern. It should be noted that when the material of the structural layer (e.g., a photoresist pattern 600 described below) includes the photoresist, the structural layer may be directly exposed by means of the mask to form the desired pattern.

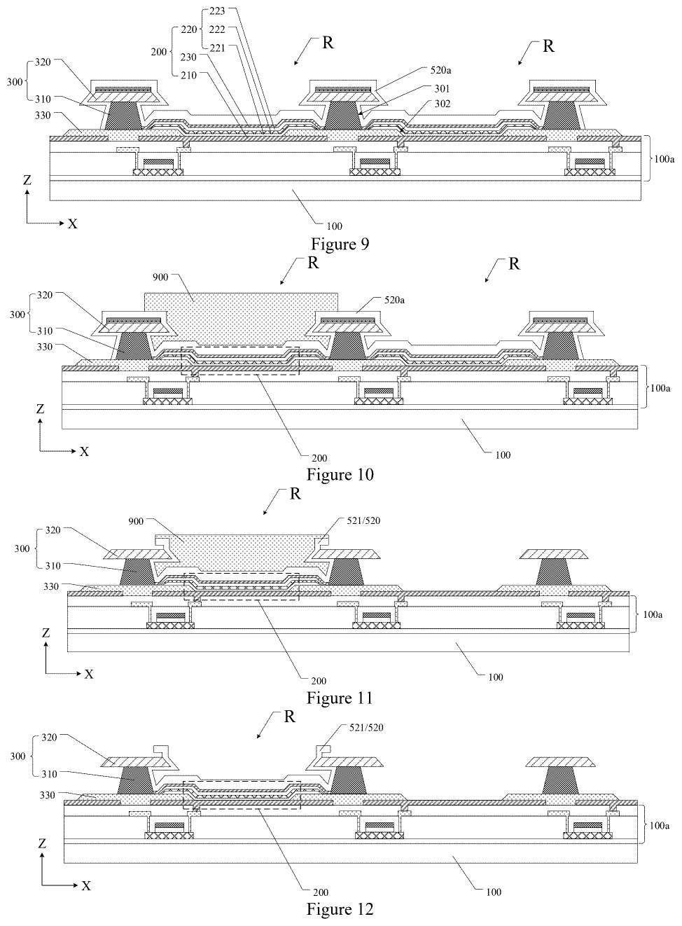

As shown in FIGS. 9 and 5B, a light-emitting unit 220 and a second electrode 230 are evaporated on the substrate 100 to form a light-emitting device 200 (a light-emitting device R that emits red light) in each of the isolation openings 301 of the isolation structure 300, and in this stage, the light-emitting unit 220 and a third electrode 230 may also be formed in the non-display area 11c. In this process, the evaporation is carried out without the mask, and the evaporated material is also deposited on the crown 320. It should be noted that, in the actual process, the evaporated material will be deposited on an upper surface facing away from the substrate 100 and a sidewall (not shown) of the first crown 320; and an encapsulation film 520a is then formed by deposition to cover the light-emitting device 200, the isolation structure 300, the dam 350, and the spacer layer 400. For example, a light-emitting layer in the evaporated light-emitting unit 220 may emit red light.

As shown in FIGS. 10 and 5B, the photoresist is formed (e.g., coated) on the substrate 100 on which the encapsulation film 520a is formed, and then is subjected to a patterning process to form a photoresist pattern 900, the photoresist pattern 900 covering only some of the isolation openings 301 of the isolation structure 300.

It should be noted that for the display module to be ultimately prepared, if the light-emitting devices formed in the adjacent isolation openings emit light in the same color, then the photoresist pattern 900 is required to cover the two adjacent isolation openings 301 and cover a portion of the isolation structure 300 between the two adjacent isolation openings 301.

As shown in FIGS. 11 and 5B, in the display area, a surface of the display module is etched with the photoresist pattern 900 as a mask to remove the encapsulation film 520a, the second electrode 230, and the light-emitting unit 220 that are not covered by the photoresist pattern 900, and the remaining part of the encapsulation film 520a forms a second inorganic encapsulation layer 520 (an encapsulation units 521 included therein).

In the above process, in the non-display area 11c, the second electrode 230, the light-emitting unit 220, and the encapsulation film 520a covering the second electrode 230 and the light-emitting unit 220 are removed, and the second inorganic encapsulation layer 520 will not be formed on the surface of the spacer layer 400.

As shown in FIGS. 12 and 5B, the remaining photoresist pattern 900 is removed, and then the light-emitting devices 200 that emit red light (R) and the encapsulation units 521 covering the light-emitting devices 200 are formed in the display module.

The light-emitting devices 200 that emit green light and the light-emitting devices 200 that emit blue light are formed in other isolation openings 301, respectively, by repeating the above process steps, and thus the display module as shown in FIGS. 5A and 5B is formed.

As shown in FIGS. 12, 5A and 5B, the preparation of a third encapsulation layer 530 and a first inorganic encapsulation layer 510 may be continued, a touch functional layer 800 is then formed on the first inorganic encapsulation layer 510, and a polarizer 600 is then attached.

The structure, preparation, and other content of the isolation structure 300 (or referred to as a partition structure) are further described in patents PCT/CN 2023/134518, 202310759370.2, 202310740412.8, 202310707209.0, 202311346196.5, 202310771071.0, 202311117143.6 and 202310692671.8 for reference.

At least one embodiment of the disclosure provides a display device, which may include the display module of the above embodiments. For example, the display device may be a television, a digital camera, a cell phone, a watch, a tablet computer, a laptop computer, a navigator, and any other product or component having a display function.

The above descriptions are merely some embodiments of the specification but not intended to limit the specification, and any modifications, equivalent replacements, combination, etc. made within the spirit and principle of the specification should be included within the scope of protection of the specification.

1. A display module, comprising a display area and a non-display area, wherein the display module comprises:
a substrate;
a first signal line, located on the substrate;
an inorganic protective layer, located at least in the non-display area and on a side of the first signal line away from the substrate;
a spacer layer, located at least in the non-display area and between the inorganic protective layer and the substrate; and
a polarizer, located on a side of the inorganic protective layer facing away from the substrate and covering the display area and extending to the non-display area;
wherein, in the non-display area, the polarizer comprises a first boundary, and an overlap region of an orthographic projection of the first signal line on the substrate and an orthographic projection of the spacer layer on the substrate overlaps with an orthographic projection of the first boundary on the substrate.

2. The display panel according to claim 1, wherein in the non-display area, the inorganic protective layer comprises a second boundary, and the overlap region of the orthographic projection of the first signal line on the substrate and the orthographic projection of the spacer layer on the substrate overlaps with an orthographic projection of the second boundary on the substrate.

3. The display panel according to claim 2, wherein the orthographic projection of the first boundary on the substrate is located on a side of the orthographic projection of the second boundary on the substrate close to the display area;
an overlap region of the orthographic projection of the first signal line on the substrate, the orthographic projection of the spacer layer on the substrate and an orthographic projection of the inorganic protective layer on the substrate overlaps with the orthographic projection of the first boundary on the substrate.

4. The display panel according to claim 2, wherein, a distance between the orthographic projection of the first boundary on the substrate and the orthographic projection of the second boundary on the substrate is greater than or equal to 130 μm and less than or equal to 220 μm;
the non-display area further comprises a bend area, and the orthographic projection of the second boundary on the substrate is located between the display area and the bend area.

5. The display module according to claim 1, wherein in the non-display area, the spacer layer comprises a third boundary, and an orthographic projection of the third boundary on the substrate is located on a side of the orthographic projection of the first boundary on the substrate close to the display area;
in the non-display area, the inorganic protective layer comprises a second boundary, and the orthographic projection of the third boundary on the substrate is located on a side of an orthographic projection of the second boundary on the substrate close to the display area.

6. The display module according to claim 5, wherein in the non-display area, a distance between the orthographic projection of the third boundary on the substrate and the orthographic projection of the first boundary on the substrate is greater than or equal to 80 μm and less than or equal to 170 μm;
the distance between the orthographic projection of the third boundary on the substrate and the orthographic projection of the second boundary of the inorganic protective layer on the substrate is greater than or equal to the sum of an attachment tolerance and an alignment tolerance of the polarizer.

7. The display module according to claim 1, further comprising at least one dam located in the non-display area, wherein an orthographic projection of the dam on the substrate is located between the display area and the orthographic projection of the first boundary on the substrate;
the spacer layer is located on a side of the dam away from the display area, a first gap is provided between the spacer layer and the dam adjacent to the spacer layer, and the inorganic protective layer located in the first gap is in contact with the first signal line; and
the orthographic projection of the first boundary on the substrate is located on a side of an orthographic projection of the first gap on the substrate away from the display area.

8. The display module according to claim 7, wherein the at least one dam comprises at least two dams, which are arranged in a direction away from the display area, a second gap is provided between adjacent dams, and the inorganic protective layer located in the second gap is in contact with the first signal line;
the orthographic projection of the first boundary on the substrate is located on a side of an orthographic projection of the second gap on the substrate away from the display area.

9. The display module according to claim 7, the inorganic protective layer is located on a side of the dam away from the substrate, and the orthographic projection of the dam on the substrate overlaps with an orthographic projection of the inorganic protective layer on the substrate;
a sidewall of a portion of the first signal line that is located in the first gap has a notch, and a sidewall of a portion of the first signal line that is covered by the spacer layer has a flatness flatter than that of the sidewall of the portion of the first signal line that is located in the first gap;
a minimum thickness of the inorganic protective layer between the portion of the first signal line that is covered by the spacer layer and the first boundary is greater than a minimum thickness of the inorganic protective layer corresponding to the sidewall of the portion of the first signal line that is located in the first gap.

10. The display module according to claim 1, further comprising a first inorganic encapsulation layer and a pixel defining layer, wherein, in the non-display area, at least a portion of the first inorganic encapsulation layer is used as at least a portion of the inorganic protective layer, and at least a portion of the pixel defining layer is used as at least a portion of the inorganic protective layer;
in the non-display area, the spacer layer comprises a third boundary, the pixel defining layer comprises a fifth boundary, and an orthographic projection of the fifth boundary on the substrate is located on a side of an orthographic projection of the third boundary on the substrate away from the display area;
in the non-display area, the first inorganic encapsulation layer comprises a sixth boundary, and an orthographic projection of the sixth boundary on the substrate is located on the side of the orthographic projection of the third boundary on the substrate away from the display area;
in the non-display area, the orthographic projection of the fifth boundary of the pixel defining layer on the substrate is located on a side of the orthographic projection of the sixth boundary of the first inorganic encapsulation layer on the substrate close to the display area;
in the non-display area, the orthographic projection of the fifth boundary of the pixel defining layer on the substrate is located on a side of the orthographic projection of the first boundary on the substrate close to the display area;
in the non-display area, the orthographic projection of the sixth boundary of the first inorganic encapsulation layer on the substrate is located on the side of the orthographic projection of the first boundary on the substrate close to the display area;
in the non-display area, the first inorganic encapsulation layer is in contact with the pixel defining layer; and
the thickness of the pixel defining layer is less than the thickness of the first inorganic encapsulation layer.

11. The display module according to claim 1, further comprising a second signal line, wherein the second signal line is located in the non-display area and between the spacer layer and the substrate, the spacer layer is provided with a via hole in the non-display area, and an orthographic projection of the via hole on the substrate overlaps with an orthographic projection of a portion of the second signal line on the substrate.

12. The display module according to claim 11, the orthographic projection of the first boundary on the substrate is located between the display area and the orthographic projection of the via hole on the substrate;
a distance between the orthographic projection of the first boundary on the substrate and the orthographic projection of the via hole on the substrate in a direction perpendicular to the first boundary or away from the display area is greater than or equal to 0.09 mm;
the second signal line and the first signal line are disposed in the same layer and made of the same material;
the first signal line is a power line, and the second signal line is a touch trace;
wherein the display panel further comprises a bend area, and the via hole is located between the display area and the bend area; and
the display panel further comprises a binding area located on a side of the bend area away from the display area.

13. The display module according to claim 11, wherein
in the non-display area, the inorganic protective layer comprises a second boundary, and an orthographic projection of the second boundary on the substrate is located between the display area and the orthographic projection of the via hole on the substrate;
wherein, a distance between the orthographic projection of the second boundary of the inorganic protective layer on the substrate and the orthographic projection of the via hole on the substrate is greater than or equal to 0.09 mm; and
wherein, the distance of the orthographic projection of the second boundary of the inorganic protective layer on the substrate and the orthographic projection of the via hole on the substrate is greater than or equal to the sum of an attachment tolerance and an alignment tolerance of the polarizer.

14. The display module according to claim 11, further comprising a third signal line, wherein the third signal line is electrically connected to the second signal line through the via hole, and the third signal line is located between the inorganic protective layer and the polarizer; and
the display module further comprises a touch functional layer comprising a touch electrode, the touch electrode being electrically connected to the third signal line and located in the display area.

15. The display module according to claim 2, further comprising a touch functional layer, wherein the touch functional layer comprises at least two conductive layers and an inorganic insulating layer between the conductive layers, and at least a portion of the inorganic insulating layer is used as at least a portion of the inorganic protective layer in the non-display area;
in the non-display area, the spacer layer comprises a third boundary, the inorganic insulating layer comprises an eighth boundary, and an orthographic projection of the eighth boundary on the substrate is located on a side of the orthographic projection of the first boundary and the third boundary on the substrate away from the display area;
and at least a portion of the eighth boundary of the inorganic insulating layer located in the non-display area is the second boundary.

16. The display module according to claim 15, the display module further comprises a first inorganic encapsulation layer located between the touch functional layer and the substrate;
the display module further comprises a touch buffer layer located between the first inorganic encapsulation layer and the touch functional layer and covering the display area and extending to the non-display area; in the non-display area, at least a portion of the touch buffer layer is used as at least a portion of the inorganic protective layer;
in the non-display area, the touch buffer layer comprises a seventh boundary, and an orthographic projection of the seventh boundary on the substrate is located on the side of the orthographic projection of the first boundary and the third boundary on the substrate away from the display area; and
in the non-display area, an orthographic projection of a sixth boundary of the first inorganic encapsulation layer on the substrate is located on a side of an orthographic projection of a boundary of the touch buffer layer on the substrate close to the display area, and at least a portion of the seventh boundary of the touch buffer layer in the non-display area is the second boundary.

17. The display module according to claim 1, further comprising at least one dam located in the non-display area, wherein one of the at least one dam is the spacer layer, and an overlap region of the orthographic projection of the first signal line on the substrate and an orthographic projection of the dam on the substrate overlaps with the orthographic projection of the first boundary on the substrate;
an overlap region of the orthographic projection of the first signal line on the substrate and an orthographic projection of the dam that is furthest from the display area on the substrate overlaps with the orthographic projection of the first boundary on the substrate;
orthographic projections of all of the dams on the substrate are located within an orthographic projection of the inorganic protective layer on the substrate;
wherein, with respect to the dam of which the orthographic projection on the substrate overlaps with the orthographic projection of the first boundary on the substrate, the width of the dam is greater than or equal to 0.09 mm in a direction from the display area to the non-display area; and
with respect to the dam of which the orthographic projection on the substrate overlaps with the orthographic projection of the first boundary on the substrate, the width of the dam is greater than or equal to the sum of an attachment tolerance and an alignment tolerance of the polarizer in the direction from the display area to the non-display area.

18. The display module according to claim 1, comprising:
a light-emitting device layer located in the display area and comprising a plurality of light-emitting devices; and
an isolation structure located on the substrate and having a plurality of isolation openings, at least a portion of each light-emitting device being located in a corresponding isolation opening;
a pixel defining layer, wherein the pixel defining layer is located on the substrate and is provided with pixel openings, the pixel openings being in communication with corresponding isolation openings;
wherein the pixel defining layer is an inorganic film layer;
in the non-display area, at least a portion of the pixel defining layer is used as at least a portion of the inorganic protective layer; and
the pixel defining layer covers the display area and extends to the non-display area, and in the non-display area, the orthographic projection of the first boundary of the polarizer on the substrate coincides with an orthographic projection of a fifth boundary of the pixel defining layer on the substrate; or in the non-display area, the orthographic projection of the first boundary of the polarizer on the substrate is located on a side of the orthographic projection of the fifth boundary of the pixel defining layer on the substrate away from the display area.

19. The display module according to claim 18, wherein the isolation structure comprises a support and a crown located on a side of the support facing away from the substrate, and an orthographic projection of the support on the substrate is located within an orthographic projection of the crown on the substrate;
the light-emitting device comprises a first electrode, a light-emitting unit and a second electrode which are stacked sequentially on the substrate in a direction away from the substrate, and
the light-emitting unit and the second electrode of each of the light-emitting devices are located in the corresponding isolation opening;
the second electrode is electrically connected to the first signal line; the support is a conductive structure and the second electrode is electrically connected to a sidewall of the support; and
the pixel defining layer comprises a pixel define portion located on a side of the first electrode away from the substrate and covering an edge of the first electrode, and the first electrode is exposed from the pixel opening,
wherein the isolation structure further comprises:
an auxiliary support located between the support and the substrate;
wherein the orthographic projection of the support on the substrate is located within an orthographic projection of the auxiliary support on the substrate;
the auxiliary support is a conductive structure, and the second electrode of the light-emitting device is electrically connected to the auxiliary support;
the display module further comprises a second inorganic encapsulation layer located on a side of the light-emitting devices away from the substrate, wherein
the second inorganic encapsulation layer comprises a plurality of encapsulation units which are spaced apart from each other and which correspond to the isolation openings, the encapsulation units covering the light-emitting devices confined by the corresponding isolation openings, and
in the non-display area, the orthographic projection of the spacer layer on the substrate does not overlap with an orthographic projection of the second inorganic encapsulation layer on the substrate; the thickness of the pixel defining layer is less than the thickness of the second inorganic encapsulation layer;
the display module further comprises a first inorganic encapsulation layer located on a side of the second inorganic encapsulation layer away from the substrate, and in the non-display area, at least a portion of the first inorganic encapsulation layer is used as at least a portion of the inorganic protective layer;
the thickness of the pixel defining layer is less than the thickness of the first inorganic encapsulation layer;
the display module further comprises a third encapsulation layer located between the first inorganic encapsulation layer and the second inorganic encapsulation layer; the third encapsulation layer is an organic layer; and
the display module further comprises at least one dam located in the non-display area, and the third encapsulation layer is located on a side of the at least one dam close to the display area.

20. The display module according to claim 1, further comprising a light-emitting device layer, wherein the light-emitting device layer is located in the display area and comprises a plurality of light-emitting devices, the light-emitting device comprising a first electrode, at least two light-emitting units stacked in a thickness direction of the substrate and a second electrode which are stacked sequentially on the substrate in a direction away from the substrate, and the second electrode being electrically connected to the first signal line;
wherein the polarizer comprises a first protective film, a linear polarization layer, and a second protective film which are stacked sequentially in a direction away from the substrate;
the first protective film comprises a triacetate film layer,
the linear polarization layer comprises a polyvinyl alcohol film layer; and the second protective film comprises a triacetate film layer,
the non-display area of the display module further comprises a bend area; the orthographic projection of the first boundary on the substrate is located between the display area and the bend area;
a distance between the orthographic projection of the first boundary on the substrate and the bend area is greater than or equal to 160 μm and less than or equal to 250 μm;
the non-display area of the display module further comprises a binding area located on a side of the bend area away from the display area, the binding area being provided with a binding pin to which the first signal line is electrically connected; the display module further comprises a filling layer located between the polarizer and the inorganic protective layer;
in the non-display area, the filling layer comprises a fourth boundary, and an orthographic projection of the fourth boundary on the substrate is located on a side of the orthographic projection of the first boundary on the substrate away from the display area.
